(19) United States
(12) Patent Application Publication
(10) Pub. No.: US 2026/0182146 A1
(43) Pub. Date: Jun. 25, 2026

(54) Display Substrate, Manufacturing Method Therefor, and Display Apparatus

(71) Applicants: Chongqing BOE Display Technology Co.,Ltd., Chongqing (CN); BOE Technology Group Co., Ltd., Beijing (CN)

(72) Inventors: Rui WANG, Beijing (CN); Weidi XIA, Beijing (CN); Chao ZENG, Beijing (CN); Ming HU, Beijing (CN); Haijun QIU, Beijing (CN); Jian GUO, Beijing (CN); Xueguang HAO, Beijing (CN); Lang LIU, Beijing (CN)

(21) Appl. No.: 18/839,443

(22) PCT Filed: Oct. 27, 2023
(86) PCT No.: PCT/CN2023/127315

§ 371 Date: Aug. 19, 2024

(51) Int. Cl. H10K 59/121; H10K 59/12; H10K 59/131

(52) U.S. Cl. CPC H10K 59/1213; H10K 59/1201; H10K 59/1216; H10K 59/131

(57) ABSTRACT

Disclosed are a display substrate and a manufacturing method therefor, and a display apparatus. The display substrate includes a plurality of circuit units forming a plurality of unit rows and a plurality of unit columns, at least one circuit unit includes a pixel drive circuit and a plurality of scan signal lines connected to the pixel drive circuit, the pixel drive circuit at least includes a plurality of transistors; in the direction perpendicular to the display substrate, the display substrate at least includes a first gate metal layer (GATE 1) arranged on the substrate (101) and a first source drain metal layer (SD1) arranged on a side of the first gate metal layer (GATE 1) away from the substrate (101), a gate electrode of at least one transistor is arranged in the first gate metal layer (GATE 1).

### CROSS-REFERENCE TO RELATED APPLICATION

The present application is a U.S. National Phase Entry of International Application No. PCT/CN 2023/127315 having an international filing date of Oct. 27, 2023. The above-identified application is hereby incorporated by reference.

### TECHNICAL FIELD

The present disclosure relates to, but is not limited to, the field of display technologies, and particularly to a display substrate and a manufacturing method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of claims.

In one aspect, the present disclosure provides a display substrate, the display substrate includes a plurality of circuit units forming a plurality of unit rows and a plurality of unit columns, at least one circuit unit includes a pixel drive circuit and a plurality of scan signal lines connected to the pixel drive circuit, the pixel drive circuit at least includes a plurality of transistors; in a direction perpendicular to the display substrate, the display substrate at least includes a first gate metal layer arranged on a substrate and a first source drain metal layer arranged on a side of the first gate metal layer away from the substrate, a gate electrode of at least one transistor is arranged in the first gate metal layer, at least one scan signal line is arranged in the first source drain metal layer, and the scan signal line is connected to the gate electrode through a via.

In an exemplary implementation, the plurality of transistors at least includes a first transistor as a first initialization transistor, the first transistor at least includes a first gate electrode, the first gate electrode is connected to a fourth scan signal line, and a first electrode of the first transistor is connected to a first initial signal line; the first gate electrode is arranged in the first gate metal layer, the fourth scan signal line is arranged in the first source drain metal layer, and the fourth scan signal line is connected to the first gate electrode through a first gate via.

In an exemplary implementation, in a unit row direction, the first gate electrodes in at least one adjacent two circuit units are an interconnected integral structure.

In an exemplary implementation, in the unit row direction, at least one adjacent two circuit units share the same first gate via.

In an exemplary implementation, a shape of the first initial signal line is a straight line or a bend line extending along the unit row direction. At least one circuit unit further includes a first initial connection line, the first initial connection line has a straight line shape or a bend line shape extending along a unit column direction, and the first initial connection line is connected to the first initial signal line to form a network communication structure for transmitting a first initial signal.

In an exemplary implementation, the first initial connection line is arranged in the first gate metal layer, and the first initial signal line is arranged in the first source drain metal layer.

In an exemplary implementation, the display substrate further includes a second source drain metal layer arranged on a side of the first source drain metal layer away from the substrate, and the first initial signal line is in a straight line shape or a bend line shape extending along the unit column direction, and the first initial signal line is arranged in the second source drain metal layer.

In an exemplary implementation, the plurality of transistors at least includes a seventh transistor as a second initialization transistor, the seventh transistor at least includes a seventh gate electrode, the seventh gate electrode is connected to a first scan signal line, and a first electrode of the seventh transistor is connected to a second initial signal line; the seventh gate electrode is arranged in the first gate metal layer, the first scan signal line is arranged in the first source drain metal layer, and the first scan signal line is connected to the seventh gate electrode through a seventh gate via.

In an exemplary implementation, in a unit row direction, the seventh gate electrodes in at least one adjacent two circuit units form an interconnected integral structure.

In an exemplary implementation, the second initial signal line is in a straight line shape or a bend line shape extending along the unit row direction, and at least one circuit unit further includes a second initial connection line, the second initial connection line is in a straight line shape or a bend line shape extending along the unit column direction, and the second initial connection line is connected to the second initial signal line to form a network communication structure for transmitting the second initial signal.

In an exemplary implementation, the second initial connection line is arranged in the first gate metal layer, and the second initial signal line is arranged in the first source drain metal layer.

In an exemplary implementation, the plurality of transistors at least includes a third transistor as a drive transistor, a fifth transistor as a first light emitting control transistor, and a sixth transistor as a second light emitting control transistor, the fifth transistor at least includes a fifth gate electrode, the sixth transistor at least includes a sixth gate electrode, the fifth gate electrode is connected to a first light emitting signal line, a first electrode of the fifth transistor is connected to a first power supply line, a second electrode of the fifth transistor is connected to a first electrode of the third transistor, the sixth gate electrode is connected to a second light emitting signal line, and a first electrode of the sixth transistor is connected to a second electrode of the third transistor. The fifth gate electrode and the sixth gate electrode are arranged in the first gate metal layer, the first light emitting signal line and the second light emitting signal line are arranged in the first source drain metal layer, the first light emitting signal line is connected to the fifth gate electrode through a via, and the second light emitting signal line is connected to the sixth gate electrode through a via.

In an exemplary implementation, the plurality of transistors at least includes a third transistor as a drive transistor, a fifth transistor as a first light emitting control transistor, and a sixth transistor as a second light emitting control transistor, the fifth transistor at least includes a fifth gate electrode, the sixth transistor at least includes a sixth gate electrode, the fifth gate electrode is connected to a light emitting signal line, a first electrode of the fifth transistor is connected to a first power supply line, a second electrode of the fifth transistor is connected to a first electrode of the third transistor, the sixth gate electrode is connected to the light emitting signal line, and a first electrode of the sixth transistor is connected to a second electrode of the third transistor. The fifth gate electrode and the sixth gate electrode are arranged in the first gate metal layer, the light emitting signal line is arranged in the first source drain metal layer, and the light emitting signal line is connected to the fifth gate electrode and the sixth gate electrode through a same via.

In an exemplary implementation, in at least one circuit unit, the fifth gate electrode and the sixth gate electrode form an interconnected integral structure.

In an exemplary implementation, in a unit row direction, the sixth gate electrodes in at least one adjacent two circuit units form an interconnected integral structure.

In an exemplary implementation, the pixel drive circuit further includes a first capacitor and a second capacitor, the first capacitor at least includes a first electrode plate and a third electrode plate, an orthographic projection of the first electrode plate on the substrate at least partially overlaps with an orthographic projection of the third electrode plate on the substrate, and the second capacitor at least includes a second electrode plate and a fourth electrode plate, an orthographic projection of the second electrode plate on the substrate at least partially overlaps with an orthographic projection of the fourth electrode plate on the substrate. The first electrode plate and the second electrode plate are arranged in the first gate metal layer, and the third electrode plate and the fourth electrode plate are arranged in the first source drain metal layer, and are of an interconnected integral structure.

In an exemplary implementation, the pixel drive circuit further includes a storage capacitor, the storage capacitor at least includes a fifth electrode plate and a sixth electrode plate, an orthographic projection of the fifth electrode plate on the substrate at least partially overlaps with an orthographic projection of the sixth electrode plate on the substrate. The fifth electrode plate is arranged in the first gate metal layer, and the sixth electrode plate is arranged in the first source drain metal layer.

In another aspect, the present disclosure further provides a display apparatus, including the display substrate described above.

On the other hand, the present disclosure further provides a preparation method for a display substrate, wherein the display substrate includes a plurality of circuit units forming a plurality of unit rows and a plurality of unit columns, at least one circuit unit includes a pixel drive circuit and a plurality of scan signal lines connected to the pixel drive circuit, and the pixel drive circuit at least includes a plurality of transistors. The preparation method includes:
forming a first gate metal layer on a substrate, wherein a gate electrode of at least one transistor is arranged in the first gate metal layer; and
forming a first source drain metal layer on the first gate metal layer, wherein at least one scan signal line is arranged on the first source drain metal layer, and the scan signal line is connected to the gate electrode through a via.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a structure of a display substrate.

FIG. 3 is a schematic diagram of a planar structure of a display region in a display substrate.

FIG. 4 is a schematic diagram of a sectional structure of a display region in a display substrate.

FIG. 5 is an equivalent circuit diagram of a pixel drive circuit according to an exemplary embodiment of the present disclosure.

FIG. 6 is a schematic diagram of a planar structure of a display substrate according to an exemplary embodiment of the present disclosure.

FIG. 7 is a sectional view taken along an A-A direction in FIG. 6.

FIG. 8 is a schematic diagram of a display substrate after a pattern of a barrier shield metal layer is formed according to the present disclosure.

FIG. 9A and FIG. 9B are schematic diagrams of a display substrate after a pattern of a semiconductor layer is formed according to the present disclosure.

FIGS. 10A and 10B are schematic diagrams of a display substrate after a pattern of a first conductive layer is formed, according to the present disclosure.

FIG. 11 is a schematic diagram of a display substrate after a pattern of a third insulation layer is formed according to the present disclosure;

FIG. 12A and FIG. 12B are schematic diagrams of a display substrate after a pattern of a third conductive layer is formed, according to the present disclosure.

FIG. 13 is a schematic diagram of a display substrate after a pattern of a fourth insulation layer is formed, according to the present disclosure.

FIG. 14A and FIG. 14B are schematic diagrams of a display substrate after a pattern of a fourth conductive layer is formed according to the present disclosure.

FIG. 15 is a schematic diagram of a planar structure of yet another display substrate according to an exemplary embodiment of the present disclosure.

FIG. 16 is a sectional view taken along an A-A direction in FIG. 15.

FIG. 17 is a diagram of an equivalent circuit of another pixel drive circuit according to an exemplary embodiment of the present disclosure;

FIG. 18 is a schematic diagram of a planar structure of another display substrate according to an exemplary embodiment of the present disclosure.

FIG. 19 is a sectional view taken along a B-B direction in FIG. 18;

FIG. 20 is a schematic diagram of another display substrate after a pattern of a shield metal layer is formed according to the present disclosure.

FIG. 21A and FIG. 21B are schematic diagrams of another display substrate after a pattern of a semiconductor layer is formed according to the present disclosure.

FIGS. 22A and 22B are schematic diagrams of another display substrate after a pattern of a first conductive layer is formed, according to the present disclosure.

FIG. 23 is a schematic diagram of another display substrate after a pattern of a third insulation layer is formed according to the present disclosure;

FIGS. 24A and 24B are schematic diagrams of another display substrate after a pattern of a third conductive layer is formed, according to the present disclosure.

FIG. 25 is a schematic diagram of another display substrate after a pattern of a fourth insulation layer is formed, according to the present disclosure.

FIG. 26A and FIG. 26B are schematic diagrams of another display substrate after a pattern of a fourth conductive layer is formed according to the present disclosure;

FIG. 27 is a schematic diagram of a further planar structure of a display substrate according to an exemplary embodiment of the present disclosure.

FIG. 28 is a sectional view taken in a B-B direction in FIG. 27.

### DETAILED DESCRIPTION

To make the objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art can easily understand such a fact that implementation modes and contents may be changed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of various films, and a width and spacing of various signal lines may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings. Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. The “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

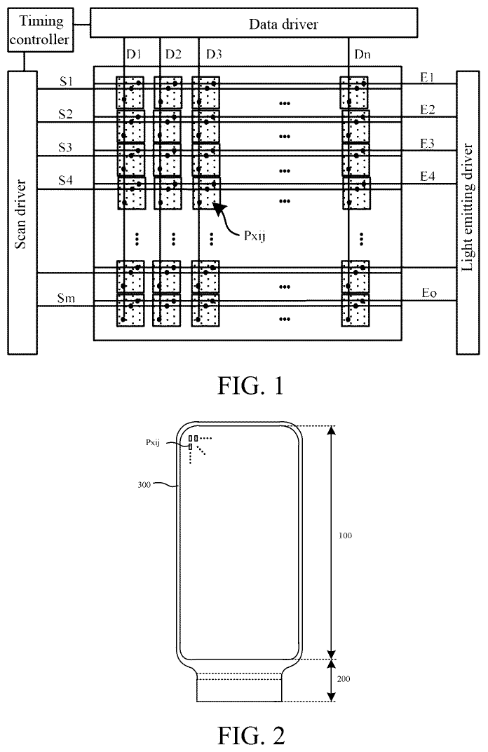

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value using the clock signal and apply a data voltage corresponding to the gray scale value to the data signal lines D1 to Dn by taking a pixel row as a unit, wherein n may be a natural number. The scan driver may generate scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be arranged on the display substrate.

FIG. 2 is a schematic diagram of a structure of a display substrate. As shown in FIG. 2, the display substrate may include a display region 100, a bonding area 200 located on a side of the display region 100, and a bezel area 300 located on another side of the display region 100. In an exemplary embodiment, the display region 100 may be a planar area including a plurality of sub-pixels that form a pixel array. The plurality of sub-pixels is configured to display a dynamic picture or a still image, and the display region 100 may be referred to as an active area (AA for short). In an exemplary implementation, the display substrate may be a flexible substrate, so that the display substrate may be deformable, for example, be curled, bent, folded, or rolled.

In exemplary implementations, the bonding region 200 may include a fan-out region, a bending region, a drive chip region, and a bonding pin region that are disposed sequentially along a direction away from the display region 100. The fan-out region is connected to the display region 100 and may at least include a plurality of data lead-out lines parallel to each other. The bending region is connected to the fan-out region and may include a composite insulation layer provided with a groove, and is configured to enable the bonding area to be bent to a back of the display region. The drive chip region may at least include an Integrated Circuit (IC for short) and is configured to be connected to the plurality of data fan-out lines. The bonding pin zone may at least include a plurality of bonding pads, and is configured to be bonded to and connected to an external Flexible Printed Circuit (FPC for short).

In an exemplary implementation mode, the bezel region 300 may include a circuit region, a power supply line region, a crack dam region, and a cutting region which are sequentially disposed along the direction away from the display region 100. The circuit region is connected to the display region 100 and may at least include a gate drive circuit which is connected to a scan signal line and a light emitting signal line of a pixel drive circuit in the display region 100. The power supply line region is connected to the circuit region and may at least include a bezel power supply lead, wherein the bezel power supply lead extends along a direction parallel to an edge of the display region and is connected to a cathode in the display region 100. The crack dam region is connected to the power supply line region and may at least include a plurality of cracks provided on the composite insulation layer. The cutting region is connected to the crack dam region and may at least include a cutting groove arranged on the composite insulation layer, and the cutting groove is configured that a cutting equipment can implement cutting along cutting grooves respectively after all film layers of the display substrate are manufactured.

In an exemplary implementation, a fan-out region in the bonding region 200 and a power supply line region in the bezel region 300 may be provided with at least one isolation dam, the isolation dam may extend along a direction parallel to the edge of the display region to form an annular structure surrounding the display region 100, wherein the edge of the display region is an edge of a side of the display region close to the bonding region, or the bezel region.

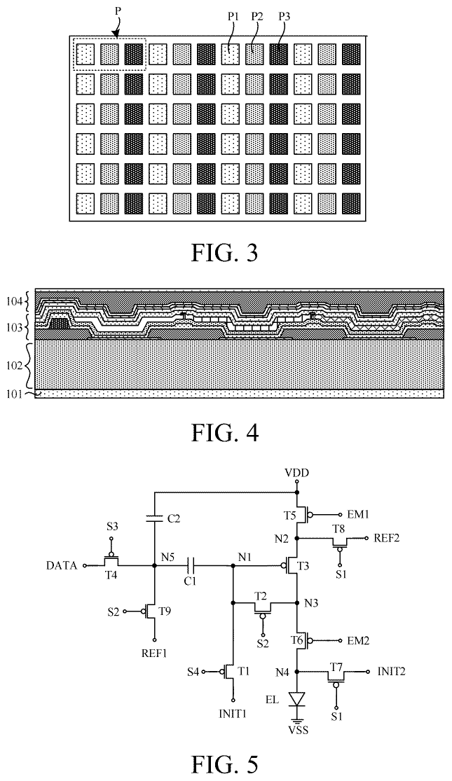

FIG. 3 is a schematic diagram of a planar structure of a display region in a display substrate. As shown in FIG. 3, the display region of the display substrate may include a plurality of pixel units P arranged in a matrix. At least one of the pixel units P may include a first sub-pixel P1 emitting light in a first color, a second sub-pixel P2 emitting light in a second color, and a third sub-pixel P3 emitting light in a third color. Each sub-pixel may include a circuit unit and a light emitting unit. The circuit unit may at least include a pixel drive circuit, the pixel drive circuit is connected to a scan signal line, a data signal line, and a light emitting signal line, respectively, and is configured to receive a data voltage transmitted by the data signal line and output a corresponding current to the light emitting device under control of the scan signal line and the light emitting signal line. The light emitting unit may at least include a light emitting device. The light emitting device is correspondingly connected to the pixel drive circuit of the sub-pixel where the light emitting device is located. The light emitting device is configured to emit light with a corresponding brightness in response to a current output by the pixel drive circuit of the sub-pixel where the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, or in a delta-shaped arrangement, etc., which is not limited here in the present disclosure.

In an exemplary implementation, a pixel unit may include four sub-pixels, and the four sub-pixels may be arranged in a manner to stand side by side horizontally, in a manner to stand side by side vertically, or in a manner of a square, which is not limited here in the present disclosure.

FIG. 4 is a schematic diagram of a sectional structure of a display region in a display substrate, illustrating the structure of three sub-pixels of a display substrate. As shown in FIG. 4, in a plane perpendicular to the display substrate, a display region of the display substrate may include a drive circuit layer 102 arranged on a substrate 101, a light emitting structure layer 103 arranged on a side of the drive circuit layer 102 away from the substrate 101, and an encapsulation structure layer 104 arranged on a side of the light emitting structure layer 103 away from the substrate 101. In some possible implementations, the display substrate may include another film or layer, such as a touch structure layer, which is not limited here in the present disclosure.

In an exemplary implementation, the substrate 101 may be a flexible substrate, or may be a rigid substrate. The drive circuit layer 102 may include a plurality of circuit units, wherein a circuit unit may at least include a pixel drive circuit, and the pixel drive circuit may include a plurality of transistors and a storage capacitor. The light emitting structure layer 103 may include multiple light emitting units, a light emitting unit may at least include a light emitting device, and the light emitting device may include an anode, an organic emitting layer, and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

An exemplary embodiment of the present disclosure provides a display substrate including a plurality of circuit units forming a plurality of unit rows and a plurality of unit columns, at least one circuit unit includes a pixel drive circuit and a plurality of scan signal lines connected to the pixel drive circuit, the pixel drive circuit at least includes a plurality of transistors; in a direction perpendicular to the display substrate, the display substrate at least includes a first gate metal layer arranged on the substrate and a first source drain metal layer arranged on a side of the first gate metal layer away from the substrate, a gate electrode of at least one transistor is arranged in the first gate metal layer, and at least one scan signal line is arranged in the first source drain metal layer, the scan signal line is connected to the gate electrode through a via.

In an exemplary implementation, the plurality of transistors at least includes a first transistor as a first initialization transistor, the first transistor at least includes a first gate electrode, the first gate electrode is connected to a fourth scan signal line, and a first electrode of the first transistor is connected to a first initial signal line; the first gate electrode is arranged in the first gate metal layer, the fourth scan signal line is arranged in the first source drain metal layer, and the fourth scan signal line is connected to the first gate electrode through a first gate via.

In an exemplary implementation, the plurality of transistors at least includes a seventh transistor as a second initialization transistor, the seventh transistor at least includes a seventh gate electrode, the seventh gate electrode is connected to a first scan signal line, and a first electrode of the seventh transistor is connected to a second initial signal line. The seventh gate electrode is arranged in the first gate metal layer, the first scan signal line is arranged in the first source drain metal layer, and the first scan signal line is connected to the seventh gate electrode through a seventh gate via.

In an exemplary implementation, the plurality of transistors at least includes a third transistor as a drive transistor, a fifth transistor as a first light emitting control transistor, and a sixth transistor as a second light emitting control transistor, the fifth transistor at least includes a fifth gate electrode, the sixth transistor at least includes a sixth gate electrode, the fifth gate electrode is connected to a first light emitting signal line, a first electrode of the fifth transistor is connected to a first power supply line, a second electrode of the fifth transistor is connected to a first electrode of the third transistor, the sixth gate electrode is connected to a second light emitting signal line, and a first electrode of the sixth transistor is connected to a second electrode of the third transistor. The fifth gate electrode and the sixth gate electrode are arranged in the first gate metal layer, the first light emitting signal line and the second light emitting signal line are arranged in the first source drain metal layer, the first light emitting signal line is connected to the fifth gate electrode through a via, and the second light emitting signal line is connected to the sixth gate electrode through a via.

In an exemplary implementation, the plurality of transistors at least includes a third transistor as a drive transistor, a fifth transistor as a first light emitting control transistor, and a sixth transistor as a second light emitting control transistor, the fifth transistor at least includes a fifth gate electrode, the sixth transistor at least includes a sixth gate electrode, the fifth gate electrode is connected to a light emitting signal line, a first electrode of the fifth transistor is connected to a first power supply line, a second electrode of the fifth transistor is connected to a first electrode of the third transistor, the sixth gate electrode is connected to the light emitting signal line, and a first electrode of the sixth transistor is connected to a second electrode of the third transistor. The fifth gate electrode and the sixth gate electrode are arranged in the first gate metal layer, the light emitting signal line is arranged in the first source drain metal layer, and the light emitting signal line is connected to the fifth gate electrode and the sixth gate electrode through a same via.

In an exemplary embodiment, the pixel drive circuit further includes a first capacitor and a second capacitor, the first capacitor at least includes a first electrode plate and a third electrode plate, an orthographic projection of the first electrode plate on the substrate at least partially overlaps with an orthographic projection of the third electrode plate on the substrate, and the second capacitor at least includes a second electrode plate and a fourth electrode plate, an orthographic projection of the second electrode plate on the substrate at least partially overlaps with an orthographic projection of the fourth electrode plate on the substrate. The first electrode plate and the second electrode plate are arranged in the first gate metal layer, and the third electrode plate and the fourth electrode plate are arranged in the first source drain metal layer, and are of an interconnected integral structure.

In an exemplary implementation, the pixel drive circuit further includes a storage capacitor, the storage capacitor includes at least a fifth electrode plate and a sixth electrode plate, an orthographic projection of the fifth electrode plate on the substrate at least partially overlaps with an orthographic projection of the sixth electrode plate on the substrate. The fifth electrode plate is arranged in the first gate metal layer, and the sixth electrode plate is arranged in the first source drain metal layer.

The display substrate in the present disclosure is illustrated with examples below through some exemplary embodiments.

FIG. 5 is an equivalent circuit diagram of a pixel drive circuit according to an exemplary embodiment of the present disclosure. As shown in FIG. 5, the pixel drive circuit according to the exemplary embodiment of the present disclosure may be of a 9T2C structure, and may include nine transistors (a first transistor T1 to a ninth transistor T9) and two capacitors (a first capacitor C1 and a second capacitor C2), and the pixel drive circuit is connected to 12 signal lines (a first scan signal line S1, a second scan signal line S2, a third scan signal line S3, a fourth scan signal line S4, a first light emitting signal line EM1, a second light emitting signal line EM2, a first initial signal line INIT1, a second initial signal line INIT2, a first reference signal line REF1, a second reference signal line REF2, a data signal line DATA and a first power supply line VDD), respectively.

In an exemplary implementation, the pixel drive circuit may include a first node N1, a second node N2, a third node N3, a fourth node N4, and a fifth node N5. Herein, the first node N1 is connected to a second electrode of the first transistor, a first electrode of the second transistor T2, a gate electrode of the third transistor T3, and a first terminal of the first capacitor C1, respectively, the second node N2 is connected to the a first electrode of the third transistor T3, a second electrode of the eighth transistor T8, and a second electrode of the fifth transistor T5, respectively, the third node N3 is connected to a second electrode of the second transistor T2, a second electrode of the third transistor T3, and a first electrode of the sixth transistor T6, respectively, the fourth node N4 is connected to a second electrode of the sixth transistor T6 and a second electrode of the seventh transistor T7, respectively, and the fifth node N5 is connected to a second electrode of the fourth transistor T4, a second electrode of the ninth transistor T9, a second terminal of the first capacitor C1, and a second terminal of the second capacitor C2, respectively.

In an exemplary implementation, a first terminal of the first capacitor Cl is connected to the first node N1, a second terminal of the first capacitor C1 is connected to the fifth node N5, a first terminal of the second capacitor C2 is connected to the first power supply line VDD, and a second terminal of the second capacitor C2 is connected to the fifth node N5.

In an exemplary implementation, the first transistor T1 may be referred to as a first initialization transistor, a gate electrode of the first transistor Tl is connected to the fourth scan signal line S4, a first electrode of the first transistor T1 is connected to the first initial signal line INIT1, and the second electrode of the first transistor is connected to the first node N1. When an ON level signal is applied to the fourth scan signal line S4, the first transistor T1 transmits a first initial voltage to the gate electrode of the third transistor T3 and the first terminal of the first capacitor C1, thereby releasing charges accumulated in the first capacitor C1 and achieving initialization.

In an exemplary implementation, the second transistor T2 may be referred to as a compensation transistor, a gate electrode of the second transistor T2 is connected to the second scan signal line S2, the first electrode of the second transistor T2 is connected to the first node N1, and the second electrode of the second transistor T2 is connected to the third node N3. When the ON level signal is applied to the second scan signal line S2, the second transistor T2 connects the first node N1 and the third node N3.

In an exemplary implementation, the gate electrode of the third transistor T3 is connected to the first node N1, the first electrode of the third transistor T3 is connected to the second node N2, and the second electrode of the third transistor T3 is connected to the third node N3. The third transistor T3 may be referred to as a drive transistor and the third transistor T3 determines a magnitude of a drive current according to a potential difference between the gate electrode and the first electrode of the third transistor T3.

In an exemplary implementation mode, the fourth transistor T4 may be referred to as a data writing transistor, a gate electrode of the fourth transistor T4 is connected to the third scan signal line S3, a first electrode of the fourth transistor T4 is connected to a data signal line DATA, and the second electrode of the fourth transistor T4 is connected to the fifth node N5. When an ON level signal is applied to the third scan signal line S3, the fourth transistor T4 enables a data voltage of the data signal line DATA to be input to the second terminal of the first storage C1 and the second terminal of the second capacitor C2.

In an exemplary implementation, the fifth transistor T5 may be referred to as a first light emitting control transistor, a gate electrode of the fifth transistor T5 is connected to the first light emitting signal line EM1, a first electrode of the fifth transistor T5 is connected to the first power supply line VDD, and the second electrode of the fifth transistor T5 is connected to the second node N2. The sixth transistor T6 may be referred to as a second light emitting control transistor, a gate electrode of the sixth transistor T6 is connected to the second light emitting signal line EM2, a first electrode of the sixth transistor T6 is connected to the third node N3, and the second electrode of the sixth transistor T6 is connected to the fourth node N4. When an ON level signal is applied to the first light emitting signal line EM1 and the second light emitting signal line EM2, the fifth transistor T5 and the sixth transistor T6 form a drive current path between the first power supply line VDD and the second power supply line VSS to enable the light emitting device EL to emit light.

In an exemplary implementation, the seventh transistor T7 may be referred to as a second initialization transistor, a gate electrode of the seventh transistor T7 is connected to the first scan signal line S1, a first electrode of the seventh transistor T7 is connected to the second initial signal line INIT2, and the second electrode of the seventh transistor T7 is connected to the fourth node N4. When an ON level signal is applied to the first scan signal line S1, the seventh transistor T7 transmits a second initial voltage to a first electrode of the light emitting device EL, which releases charges accumulated in the first electrode of the light emitting device EL and achieves initialization.

In an exemplary implementation, the eighth transistor T8 may be referred to as a first reference transistor, a gate electrode of the eighth transistor T8 is connected to the first scan signal line S1, a first electrode of the eighth transistor T8 is connected to the second reference signal line REF2, and the second electrode of the eighth transistor T8 is connected to the second node N2. When an ON level signal is applied to the first scan signal line S1, the eighth transistor T8 transmits a second reference signal to the second node N2.

In an exemplary implementation, the ninth transistor T9 may be referred to as a second reference transistor, a gate electrode of the ninth transistor T9 is connected to the second scan signal line S2, a first electrode of the ninth transistor T9 is connected to the first reference signal line REF1, and the second electrode of the ninth transistor T9 is connected to the fifth node N5. When an ON level signal is applied to the second scan signal line S2, the ninth transistor T9 transmits a first reference signal to the fifth node N5.

In an exemplary implementation, a first electrode of a light emitting device EL is connected to the fourth node N4, and a second electrode of the light emitting device EL is connected to the second power supply line VSS. The light emitting device EL may be an OLED including a first electrode (anode), an organic light emitting layer, and a second electrode (cathode) which are stacked, or may be a QLED including a first electrode (anode), a quantum dot light emitting layer, and a second electrode (cathode) which are stacked.

In an exemplary implementation, a signal of the first power supply line VDD is a high-level signal continuously provided, and a signal of the second power supply line VSS is a low-level signal continuously provided.

In an exemplary implementation, the first transistor T1 to the ninth transistor T9 may be P-type transistors, or may be N-type transistors. Use of a same type of transistors in a pixel drive circuit may simplify a process flow, reduce a process difficulty of a display panel, and improve a product yield. In some possible implementation modes, the first transistor T1 to the ninth transistor T9 may include a P-type transistor and an N-type transistor.

In an exemplary implementation, for all of the first transistor T1 to the ninth transistor T9, low temperature poly silicon thin film transistors may be used, oxide thin film transistors may be used, or both of low temperature poly silicon thin film transistors and oxide thin film transistors may be used. An active layer of a low temperature poly silicon thin film transistor is made of Low Temperature Poly silicon (LTPS for short), and an active layer of an oxide thin film transistor is made of an oxide semiconductor (Oxide). The low temperature poly silicon thin film transistor has advantages, such as a high mobility and fast charging, and the oxide thin film transistor has advantages, such a low leakage current. The low temperature poly silicon thin film transistor and the oxide thin film transistor are integrated on one display substrate, that is, an LTPS+Oxide (LTPO for short) display substrate, so that advantages of the low temperature poly silicon thin film transistor and the oxide thin film transistor may be utilized, low-frequency drive may be achieved, power consumption may be reduced, and display quality may be improved.

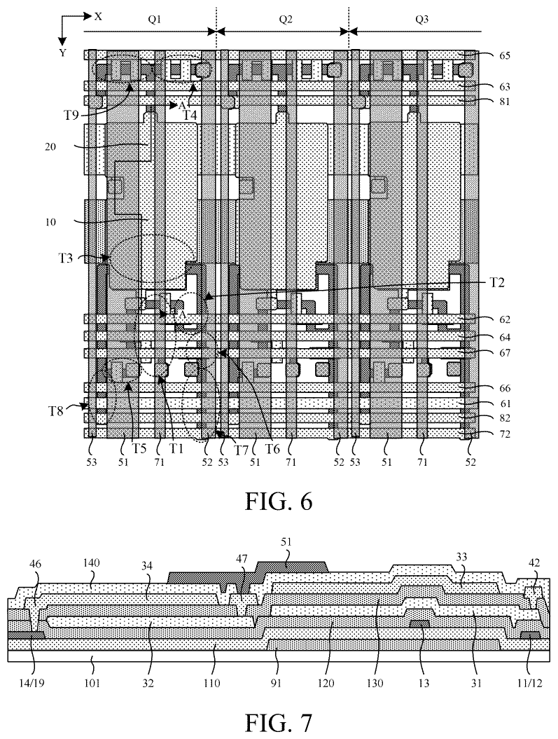

FIG. 6 is a schematic diagram of a planar structure of a display substrate in an exemplary embodiment of the present disclosure, illustrating a structure of pixel drive circuits in three circuit units (first circuit unit Q1, second circuit unit Q2, and third circuit unit Q3) in the display substrate, and FIG. 7 is a sectional view in the A-A direction of FIG. 6. In an exemplary implementation, the display substrate may include a drive circuit layer arranged on a substrate, and a light emitting structure layer arranged on a side of the drive circuit layer away from the substrate. The drive circuit layer may include, at least, a plurality of circuit units, the light emitting structure layer may include, at least, a plurality of light emitting units, wherein at least one circuit unit includes a pixel drive circuit, at least one light emitting unit includes a light emitting device that may include, at least, an anode, an organic light emitting layer, and a cathode, and the anode in the light emitting unit is connected to a pixel drive circuit in a corresponding circuit unit.

In an exemplary implementation, the circuit units mentioned in the present disclosure refer to regions divided according to pixel drive circuits, and the light emitting units mentioned in the present disclosure refer to regions divided according to light emitting devices. In an exemplary implementation, a position of an orthographic projection of a light emitting unit on the substrate may correspond to a position of an orthographic projection of a circuit unit on the substrate, or a position of an orthographic projection of a light emitting unit on the substrate may not correspond to a position of an orthographic projection of a circuit unit on the substrate.

In an exemplary embodiment, a plurality of circuit units sequentially disposed along a first direction X are referred to as a unit row, and a plurality of circuit units sequentially disposed along a second direction Y are referred to as a unit column. A plurality of unit rows and a plurality of unit columns form an array of circuit units arranged in an array, and the first direction X intersects with the second direction Y.

As shown in FIGS. 6 and 7, the pixel drive circuit in the at least one circuit unit may at least include a first capacitor 10, a second capacitor 20, and a plurality of transistors, the plurality of transistors may include a first transistor T1 as a first initialization transistor, a second transistor T2 as a compensation transistor, a third transistor T3 as a drive transistor, a fourth transistor T4 as a data writing transistor, a fifth transistor T5 as a first light emitting control transistor, a sixth transistor T6 as a second light emitting control transistor, a seventh transistor T7 as a second initialization transistor, an eighth transistor T8 as a first reference transistor, and a ninth transistor T9 as a second reference transistor. The first capacitor 10 may include a first electrode plate 31 and a third electrode plate 33, and the second capacitor 20 may include a second electrode plate 32 and a fourth electrode plate 34.

In an exemplary implementation, a gate electrode of the first transistor T1 is connected to a fourth scan signal line 64, a first electrode of the first transistor T1 is connected to a first initial signal line 71, and a second electrode of the first transistor T1 and a first electrode of the second transistor T2 are connected to the first electrode plate 31 though a second connection electrode 42. A second gate electrode of the second transistor T2 is connected to a second scan signal line 62, and a second electrode of the second transistor T2 is connected to a second electrode of the third transistor T3 and a first electrode of the sixth transistor T6 respectively. A gate electrode of the third transistor T3 may serve as the first electrode plate 31, and a first electrode of the third transistor T3 is connected to a second electrode of the fifth transistor T5, and a second electrode of the eighth transistor T8, respectively. A fourth gate electrode of the fourth transistor T4 is connected to a third scan signal line 63, a first electrode of the fourth transistor T4 is connected to a data signal line 52, and a second electrode of the fourth transistor T4 and a second electrode of the ninth transistor T9 are respectively connected to the fourth electrode plate 34 through a sixth connection electrode 46. A fifth gate electrode of the fifth transistor T5 is connected to a first light emitting signal line 66, and a first electrode of the fifth transistor T5 is connected to the first power supply line 51. A sixth gate electrode of the sixth transistor T6 is connected to a second light emitting signal line 67, and a second electrode of the sixth transistor T6 is connected to a second electrode of the seventh transistor T7. A gate electrode of the seventh transistor T7 is connected to a first scan signal line 61, and a first electrode of the seventh transistor T7 is connected to a second initial signal line 72. A gate electrode of the eighth transistor T8 is connected to the first scan signal line 61, and a first electrode of the eighth transistor T8 is connected to the second reference signal line 82. A ninth gate electrode of the ninth transistor T9 is connected to a fifth scan signal line 65, and a first electrode of the ninth transistor T9 is connected to a first reference signal line 81.

In an exemplary implementation, the second scan signal line 62 and the fifth scan signal line 65 may transmit a same scan signal.

In an exemplary implementation, the first scan signal line 61, the second scan signal line 62, the third scan signal line 63, the fourth scan signal line 64, the fifth scan signal line 65, the first light emitting signal line 66, the second light emitting signal line 67, the second initial signal line 72, the first reference signal line 81, and the second reference signal line 82 may be in a shape of a straight line or a bend line in which a main portion extends in a first direction X, and the first power supply line 51, the data signal line 52 and the first initial signal line 71 may be in a shape of a straight line or a bend line in which a main portion extends in a second direction Y.

In the present disclosure, “A extends along a B direction” means that A may include a main portion and a secondary portion connected to the main portion, the main portion is a line, a line segment, or a strip-shaped body, the main portion extends along the B direction, and a length of the main portion extends along the B direction is greater than a length of the secondary portion extends along another direction.

In an exemplary implementation, the at least one circuit unit may include a first reference connection line 53. The first reference connection line 53 may be in a shape of a straight line or a bend line in which a main portion extends along the second direction Y, and is connected to the first reference signal line 81, thereby achieving the mutual connection between the first reference signal line 81 in which a main portion extends along the first direction X and the first reference connection line 53 in which the main portion extends along the second direction Y, so that the first reference signal line 81 and the first reference connection line 53 form a mesh-shaped network communication structure for transmitting a first reference signal on the display substrate.

In an exemplary implementation, on a plane perpendicular to the display substrate, the display substrate may include: a barrier shield metal layer (BSM) arranged on the substrate 101, a first insulation layer 110 arranged on a side of the barrier shield metal layer away from the substrate 101, a semiconductor layer arranged on a side of the first insulation layer 110 away from the substrate 101, a second insulation layer 120 arranged on a side of the semiconductor layer away from the substrate 101, a first gate metal layer (GATE1) arranged on a side of the second insulation layer 120 away from the substrate 101, a third insulation layer 130 arranged on a side of the first gate metal layer away from the substrate 101, a first source drain metal layer (SD1) arranged on a side of the third insulation layer 130 away from the substrate 101, a fourth insulation layer 140 arranged on a side of the first source drain metal layer away from the substrate 101, and a second source drain metal layer (SD2) arranged on a side of the fourth insulation layer 140 away from the substrate 101.

In an exemplary implementation, the first electrode plate 31 of the first capacitor 10 and the second electrode plate 32 of the second capacitor 20 may be arranged in the first gate metal layer, the third electrode plate 33 of the first capacitor 10 and the fourth electrode plate 34 of the second capacitor 20 may be arranged in the first source drain metal layer, an orthographic projection of the first electrode plate 31 on the substrate at least partially overlaps with an orthographic projection of the third electrode plate 33 on the substrate, and an orthographic projection of the second electrode plate 32 on the substrate at least partially overlaps with an orthographic projection of the fourth electrode plate 34 on the substrate, and the third electrode plate 33 and the fourth electrode plate 34 may form an interconnected integral structure.

In an exemplary implementation, a first gate electrode of the first transistor T1 may be arranged in the first gate metal layer, the fourth scan signal line 64 may be arranged in the first source drain metal layer, and the fourth scan signal line 64 may be connected to the first gate electrode of the first transistor T1 through a via.

In an exemplary implementation, the second gate electrode of the second transistor T2 may be arranged in the first gate metal layer, the second scan signal line 62 may be arranged in the first source drain metal layer, and the second scan signal line 62 may be connected to the second gate electrode of the second transistor T2 through a via.

In an exemplary implementation, the fourth gate electrode of the fourth transistor T4 may be arranged in the first gate metal layer, the third scan signal line 63 may be arranged in the first source drain metal layer, and the third scan signal line 63 may be connected to the fourth gate electrode of the fourth transistor T4 through a via.

In an exemplary implementation, the fifth gate electrode of the fifth transistor T5 may be arranged in the first gate metal layer, the first light emitting signal line 66 may be arranged in the first source drain metal layer, and the first light emitting signal line 66 may be connected to the fifth gate electrode of the fifth transistor T5 through a via.

In an exemplary implementation, the sixth gate electrode of the sixth transistor T6 may be arranged in the first gate metal layer, the second light emitting signal line 67 may be arranged in the first source drain metal layer, and the second light emitting signal line 67 may be connected to the sixth gate electrode of the sixth transistor T6 through a via.

In an exemplary implementation, the ninth gate electrode of the ninth transistor T9 may be arranged in the first gate metal layer, the fifth scan signal line 65 may be arranged in the first source drain metal layer, and the fifth scan signal line 65 may be connected to the ninth gate electrode of the ninth transistor T9 through a via.

In an exemplary implementation, the first initial signal line 71 may be arranged in the second source drain metal layer, and the second initial signal line 72 may be arranged in the first source drain metal layer.

In an exemplary implementation, the first reference signal line 81 and the second reference signal line 82 may be arranged in the first source drain metal layer, and the first reference connection line 53 may be arranged in the second source drain metal layer.

As shown in FIG. 7, in an exemplary implementation, the barrier shield metal layer may at least include a barrier shield electrode 91, the semiconductor layer may at least include a first active layer 11, a second active layer 12, a third active layer 13, a fourth active layer 14, and a ninth active layer 19, and the first gate metal layer (first conductive layer) may at least include a first electrode plate 31 and a second electrode plate 32. The first source drain metal layer (third conductive layer) may at least include a third electrode plate 33, a fourth electrode plate 34, a second connection electrode 42, a sixth connection electrode 46 and a seventh connection electrode 47, the second connection electrode 42 is connected to the first electrode plate 31 through a via, the sixth connection electrode 46 is connected to the fourth active layer 14 and the ninth active layer 19 through a via, and the seventh connection electrode 47 is connected to the second electrode plate 32 through a via. The second source drain metal layer (fourth conductive layer) may at least include a first power supply line 51, the first power supply line 51 is connected to the seventh connection electrode 47 through a via.

In an exemplary implementation, the first gate metal layer (first conductive layer) may further include a first scan signal line 61, the first source drain metal layer (third conductive layer) may further include a plurality of connection electrodes, and the second source drain metal layer (fourth conductive layer) may further include a data signal line 52.

Exemplary description is made below through a preparation process of a display substrate. A “patterning process” mentioned in the present disclosure includes a treatment such as deposition of a film layer, photoresist coating on a film layer, mask exposure, development, etching, photoresist stripping, etc. for a metal material, an inorganic material, or a transparent conductive material, and includes a treatment such as organic material coating, mask exposure, development, etc. for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a substrate using deposition, coating, or other processes. If the “thin film” does not need to be processed through a patterning process in the entire preparation process, the “thin film” may also be called a “layer”. If the “thin film” needs to be processed through the patterning process in the entire preparation process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

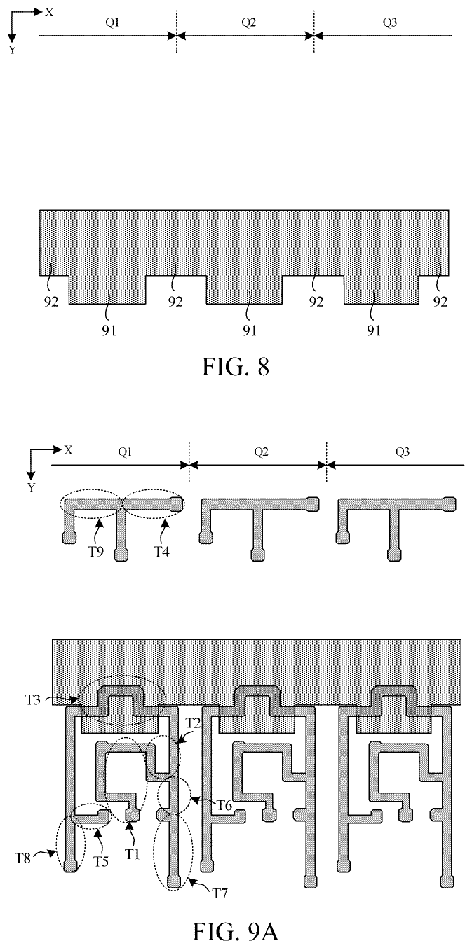

In an exemplary implementation mode, taking three circuit units (the first circuit unit Q1, the second circuit unit Q2, and the third circuit unit Q3) as an example, a preparation process of the display substrate according to the present implementation may include following operations.
(11) Forming a pattern of a barrier shield metal layer. In an exemplary implementation, forming a pattern of a barrier shield metal layer may include: depositing a barrier shield metal film on a substrate, patterning the barrier shield metal film by a patterning process, and forming a barrier shield metal layer (BSM) arranged on the substrate, as shown in FIG. 8.

In an exemplary implementation, the barrier shield metal layer of each circuit unit in the display substrate may at least include a barrier shield electrode 91 and a barrier shield connection strip 92.

In the exemplary implementation, the barrier shield electrode 91 may be in a block shape (such as a rectangle), and may be arranged in a middle region of the circuit unit in the first direction X and the second direction Y. The barrier shield electrode 91 is configured as a barrier shield layer for the third transistor T3 to shield light on the third transistor T3, reduce light intensity irradiated on the third transistor T3, reduce leakage current of the third transistor T3, and thereby reducing an influence of light on the characteristics of the third transistor T3.

In the exemplary implementation, the barrier shield connection strip 92 may be in a strip shape extending along the first direction X, and may be arranged on a side of the barrier shield electrode 91 in the first direction X or on a side of the barrier shield electrode 91 in the opposite direction of the first direction X, the first terminal of the barrier shield connection strip 92 is connected to the barrier shield electrode 91 in the present circuit unit, and the second terminal of the barrier shield connection strip 92 extends to an adjacent circuit unit and is connected to the barrier shield electrode 91 of the adjacent circuit unit.

In an exemplary implementation, the barrier shield electrode 91 and the barrier shield connection strip 92 may form an interconnected integral structure.

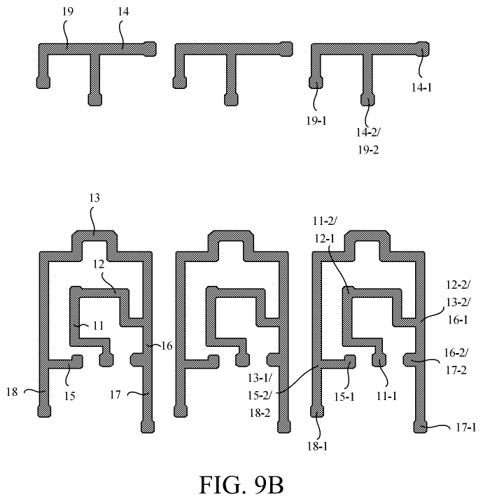

In an exemplary implementation, positions and shapes of the barrier shield metal layers in a plurality of circuit units in the first direction X may be substantially the same.
(12) Forming a pattern of a semiconductor layer. In an exemplary implementation mode, forming a pattern of a semiconductor layer may include: on the substrate on which the aforementioned pattern is formed, sequentially depositing a first insulation thin film and a semiconductor thin film, patterning the semiconductor thin film by a patterning process to form a first insulation layer covering the barrier shield metal layer, and a semiconductor layer arranged on the first insulation layer, as shown in FIGS. 9A and 9B, FIG. 9B is a schematic diagram of the semiconductor layer in FIG. 9A.

In an exemplary implementation, a semiconductor layer of each circuit unit in the display substrate may at least include: a first active layer 11 of a first transistor T1, a second active layer 12 of a second transistor T2, a third active layer 13 of a third transistor T3, a fourth active layer 14 of a fourth transistor T4, a fifth active layer 15 of a fifth transistor T5, a sixth active layer 16 of a sixth transistor T6, a seventh active layer 17 of a seventh transistor T7, an eighth active layer 18 of an eighth transistor T8 and a ninth active layer 19 of a ninth transistor T9, and the first active layer 11 to the third active layer 13 and the fifth active layer 15 to the eighth active layer 18 may be an interconnected integral structure, and the fourth active layer 14 and the ninth active layer 19 may form an interconnected integral structure.

In an exemplary implementation, in the first direction X, the eighth active layer 18 may be located at a side of the third active layer 13 in the present circuit unit in an opposite direction of the first direction X, and the sixth active layer 16 and the seventh active layer 17 may be located at a side of the third active layer 13 in the present circuit unit in the first direction X. In the second direction Y, the fourth active layer 14 and the ninth active layer 19 may be located at a side of the third active layer 13 in the present circuit unit in an opposite direction of the second direction Y, and the first active layer 11, the second active layer 12, the fifth active layer 15 to the eighth active layer 18 may be located at a side of the third active layer 13 in the second direction Y.

In an exemplary implementation, the first active layer 11 may be located at a side of the third active layer 13 of the present circuit unit in the second direction Y, the fifth active layer 15 may be located at a side of the first active layer 11 of the present circuit unit in the second direction Y, and the eighth active layer 18 may be located at a side of the fifth active layer 15 of the present circuit unit in the second direction Y. The second active layer 12 may be located at a side of the third active layer 13 of the present circuit unit in the second direction Y, the sixth active layer 16 may be located at a side of the second active layer 12 of the present circuit unit in the second direction Y, and the seventh active layer 17 may be located at a side of the sixth active layer 16 of the present circuit unit in the second direction Y.

In an exemplary implementation, the first active layer 11, the second active layer 12, the fourth active layer 14, and the ninth active layer 19 may have an “L” shape, the third active layer 13 may have an “Ω” shape, and the fifth active layer 15, the sixth active layer 16, the seventh active layer 17, and the eighth active layer 18 may have an “I” shape.

In the exemplary implementation, an orthographic projection of the third active layer 13 on the substrate at least partially overlaps with an orthographic projection of the barrier shield electrode 91 on the substrate, so that the barrier shield electrode 91 can shield the third transistor T3, reduce light intensity irradiated on the third transistor T3, reduce leakage current of the third transistor T3, and thereby reducing an influence of light on the characteristics of the third transistor T3.

In an exemplary implementation, an active layer of each transistor may include a first region, a second region, and a channel region located between the first region and the second region.

In an exemplary implementation, a second region 11-2 of the first active layer and a first region 12-1 of the second active layer may be connected to each other, such that the second region 11-2 of the first active layer may serve as the first region 12-1 of the second active layer. A first region 13-1 of the third active layer, a second region 15-2 of the fifth active layer, and a second region 18-2 of the eighth active layer may be connected to each other, such that the first region 13-1 of the third active layer may serve as the second region 15-2 of the fifth active layer and the second region 18-2 of the eighth active layer at the same time, forming a second node N2 of the pixel drive circuit. A second region 12-2 of the second active layer, a second region 13-2 of the third active layer and a first region 16-1 of the sixth active layer may be connected to each other, such that the second region 13-2 of the third active layer may serve as the second region 12-2 of the second active layer and the first region 16-1 of the sixth active layer at the same time, forming a third node N3 of the pixel drive circuit. A second region 14-2 of the fourth active layer and a second region 19-2 of the ninth active layer may be connected to each other, such that the second region 14-2 of the fourth active layer may serve as the second region 19-2 of the ninth active layer. A second region 16-2 of the sixth active layer and a second region 17-2 of the seventh active layer may be connected to each other, and the second region 16-2 of the sixth active layer may serve as the second region 17-2 of the seventh active layer, forming a fourth node N4 of the pixel drive circuit. A first region 11-1 of the first active layer, a first region 14-1 of the fourth active layer, a first region 15-1 of the fifth active layer, a first region 17-1 of the seventh active layer, a first region 18-1 of the eighth active layer, and a first region 19-1 of the ninth active layer may be disposed separately.

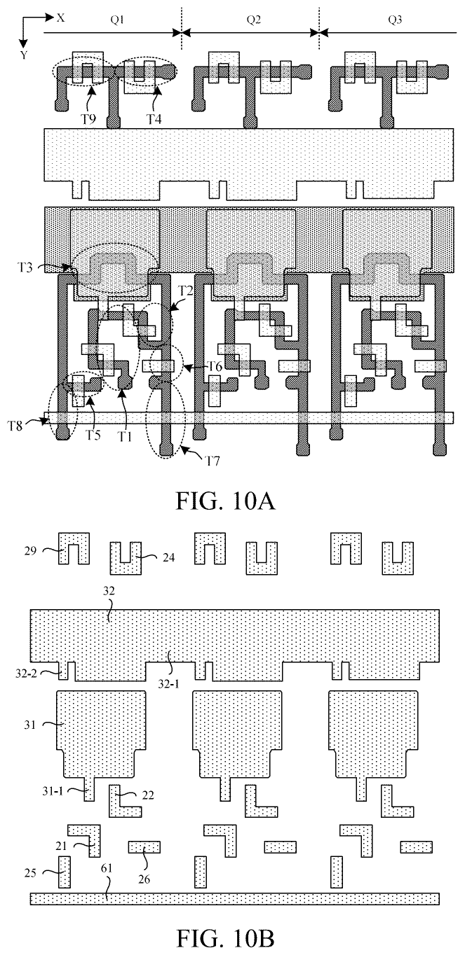

In an exemplary implementation, positions and shapes of the semiconductor layers in a plurality of circuit units in the first direction X may be substantially the same.
(13) Forming a pattern of a first conductive layer. In an exemplary implementation, forming the pattern of the first conductive layer may include: a second insulation thin film and a first conductive thin film are deposited sequentially on the substrate on which the aforementioned patterns are formed, and the first conductive thin film is patterned through a patterning process to form a second insulation layer that covers the pattern of the semiconductor layer, and a pattern of a first conductive layer arranged on the second insulation layer, as shown in FIGS. 10A and 10B, wherein FIG. 10B is a schematic diagram of the first conductive layer in FIG. 10A. In an exemplary implementation, the first conductive layer may be referred to as a first gate metal (GATE1) layer.

In an exemplary implementation, a pattern of a first conductive layer of each circuit unit in the display substrate at least includes: a first gate electrode 21, a second gate electrode 22, a fourth gate electrode 24, a fifth gate electrode 25, a sixth gate electrode 26, a ninth gate electrode 29, a first scan signal line 61, a first electrode plate 31 of a first capacitor, and a second electrode plate 32 of a second capacitor.

In an exemplary implementation, the first electrode plate 31 of the first capacitor may be in a rectangle shape, corner portions of the rectangular shape may be provided with chamfered corners or grooves, an orthographic projection of the first electrode plate 31 on the substrate at least partially overlaps with an orthographic projection of the third active layer of the third transistor T3 on the substrate, and the first electrode plate 31 may serve as an electrode plate of the first capacitor and a gate electrode of the third transistor T3 at the same time.

In an exemplary implementation, the first electrode plate 31 may be provided with a first electrode plate connection block 31-1. The first electrode plate connection block 31-1 may be in a block shape (e.g., rectangular) and may be provided on a side of the first electrode plate 31 away from the second electrode plate 32, a first terminal of the first electrode plate connection block 31-1 is connected to the first electrode plate 31, a second terminal of the first electrode plate connection block 31-1 extends in a direction away from the second electrode plate 32, and the first electrode plate connection block 31-1 is configured to be connected to a second region of the first active layer (also a first region of the second active layer) by a second connecting electrode subsequently formed.

In an exemplary implementation mode, the first electrode plate 31 and the first electrode plate connection block 31-1 may form an interconnected integral structure.

In the exemplary implementation, the second electrode plate 32 of the second capacitor may be in a rectangular shape, corner portions of the rectangular shape may be provided with chamfered corners or grooves, and the second electrode plate 32 may be located on a side of the first electrode plate 31 in an opposite direction of the second direction Y, and the second electrode plate 32 may serve as an electrode plate of the second capacitor.

In an exemplary implementation, in at least one circuit unit, an orthographic projection of the second electrode plate 32 on the substrate does not overlap with an orthographic projection of the semiconductor layer on the substrate.

In an exemplary implementation, the second electrode plate 32 may be provided with an electrode plate connection strip 32-1. The electrode plate connection strip 32-1 may be in a shape of a strip extending along the first direction X, and may be provided on a side of the second electrode plate 32 in the first direction X or on a side of the second electrode plate 32 in an opposite direction of the first direction X. A first terminal of the electrode plate connection strip 32-1 is connected to the second electrode plate 32 in the present circuit unit, and a second terminal of the electrode plate connection strip 32-1 extends to an adjacent circuit unit and is connected to a second electrode plate 32 of the adjacent circuit unit, so that the second electrode plates 32 in adjacent circuit units in one unit row are interconnected.

In an exemplary implementation, a plurality of second electrode plates 32 and a plurality of electrode plate connection strips 32-1 disposed at intervals along the first direction X may form an interconnected integral structure. Because the second electrode plate 32 is connected to a first power supply line formed subsequently, the second electrode plates 32 in an integral structure of a plurality of circuit units may be reused as a transverse power supply line extending along the first direction X, which not only ensures that a plurality of second electrode plates 32 in a unit row are at a same potential, but also reduces a voltage drop of a first power supply signal, which is beneficial to improving uniformity of the panel, avoiding display defect of the display substrate, and ensuring the display effect of the display substrate.

In an exemplary implementation, the second electrode plate 32 may be provided with a second electrode plate connection block 32-2. The second electrode plate connection block 32-2 may be in a block (e.g. rectangular) shape and may be provided on a side of the second electrode plate 32 close to the first electrode plate 31, a first terminal of the second electrode plate connection block 32-2 is connected to the second electrode plate 32, a second terminal of the second electrode plate connection block 32-2 extends in a direction close to the first electrode plate 31, and the second electrode plate connection block 32-2 is configured to be connected to the first power supply line by a seventh connection electrode formed subsequently.

In an exemplary implementation, in at least one circuit unit, the second electrode plate 32, the electrode plate connection strip 32-1 and the second electrode plate connection block 32-2 may form an interconnected integral structure.

In an exemplary implementation, the first scan signal line 61 may be in a shape of a straight line or a bend line in which a main portion extends along the first direction X, and may be located on a side of the first electrode plate 31 in the second direction Y, a region where the first scan signal line 61 overlaps the seventh active layer may serve as a gate electrode of the seventh transistor T7, and a region where the first scan signal line 61 overlaps the eighth active layer may serve as a gate electrode of the eighth transistor T8.

In an exemplary implementation, the first gate electrode 21 may be in an “L” shape, and may be located between the first electrode plate 31 and the first scan signal line 61, and a region where the first gate electrode 21 overlaps with the first active layer may serve as a gate electrode of the first transistor T1 of a double gate structure.

In an exemplary implementation, the second gate electrode 22 may be in a “L” shape, and may be located between the first electrode plate 31 and the first scan signal line 61, and a region where the second gate electrode 22 overlaps with the second active layer may serve as a gate electrode of the second transistor T2 of a double gate structure.

In an exemplary implementation, the fourth gate electrode 24 may be in an “U” shape, and may be located on a side of the second electrode plate 32 away from the first electrode plate 31, and a region where the fourth gate electrode 24 overlaps with the fourth active layer may serve as a gate electrode of the fourth transistor T4 of a double-gate structure.

In an exemplary implementation, the fifth gate electrode 25 may be in a shape of strip extending along the second direction Y, and may be located on a side of the first gate electrode 21 away from the first electrode plate 31, and a region where the fifth gate electrode 25 overlaps with the fifth active layer may serve as a gate electrode of the fifth transistor T5.

In an exemplary implementation, the sixth gate electrode 26 may be in a shape of strip extending along the first direction X, and may be located on a side of the second gate electrode 22 away from the first electrode plate 31, and a region where the sixth gate electrode 26 overlaps with the sixth active layer may serve as a gate electrode of the sixth transistor T6.

In an exemplary implementation, the ninth gate electrode 29 may have a “U” shape, and may be located on a side of the second electrode plate 32 away from the first electrode plate 31, and a region where the ninth gate electrode 29 overlaps with the ninth active layer may serve as a gate electrode of a ninth transistor T9 of a double-gate structure.

In an exemplary implementation, positions and shapes of the first conductive layers in a plurality of circuit units in the first direction X may be substantially the same.

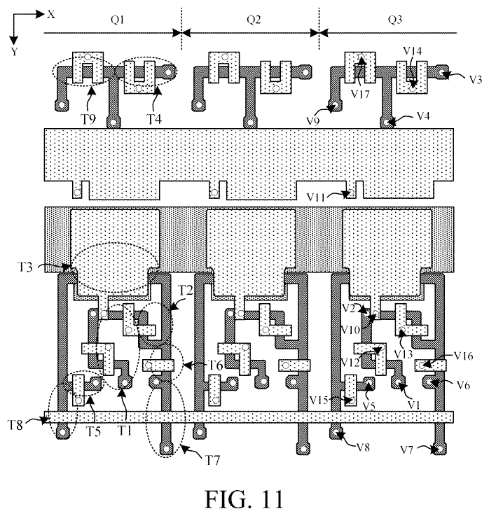

In an exemplary implementation, after the pattern of the first conductive layer is formed, a conductive processing may be performed on the semiconductor layer by using the first conductive layer as a shield, a semiconductor layer shielded by the first conductive layer forms channel regions of the first transistor T1 to the ninth transistor T9, and a semiconductor layer not shielded by the first conductive layer is made to be conductive, and all of first regions and second regions of the first active layer to the ninth active layer are made to be conductive.
(14) A pattern of a third insulation layer is formed. In an exemplary implementation, forming a pattern of a third insulation layer may include: on the substrate on which the aforementioned patterns are formed, depositing a third insulation thin film, patterning the third insulation thin film through a patterning process to form a third insulation layer that covers the first conductive layer, wherein a plurality of vias are arranged in each circuit unit, as shown in FIG. 11.

In an exemplary implementation, the plurality of vias of each circuit unit in the display substrate at least include: a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, and a seventeenth via V17.

In an exemplary implementation, an orthographic projection of the first via V1 on the substrate is within a range of an orthographic projection of a first region of the first active layer on the substrate, the third insulation layer and the second insulation layer within the first via V1 is etched away to expose a surface of the first region of the first active layer, and the first via V1 is configured to enable a subsequently formed first connection electrode to be connected to the first region of the first active layer through the via.

In an exemplary implementation, an orthographic projection of the second via V2 on the substrate is within a range of an orthographic projection of the second region of the first active layer (that is, a first region of the second active layer) on the substrate, the third insulation layer and the second insulation layer within the second via V2 are etched away to expose a surface of the second region of the first active layer (that is, the first region of the second active layer), and the second via V2 is configured to enable a subsequently formed second connection electrode to be connected to the second region of the first active layer (that is, the first region of the second active layer) through the via.

In an exemplary implementation, an orthographic projection of the third via V3 on the substrate is within a range of an orthographic projection of a first region of a fourth active layer on the substrate, the third insulation layer and the second insulation layer within the third via V3 is etched away to expose a surface of the first region of the fourth active layer, and the third via V3 is configured to enable a subsequently formed third connection electrode to be connected to the first region of the fourth active layer through the via.

In an exemplary implementation, an orthographic projection of the fourth via V4 on the substrate is within a range of an orthographic projection of a second region of the fourth active layer (that is, a second region of the ninth active layer) on the substrate, the third insulation layer and the second insulation layer within the fourth via V4 are etched away to expose a surface of the second region of the fourth active layer (that is, the second region of the ninth active layer), and the fourth via V4 is configured to enable a subsequently formed sixth connection electrode to be connected to the second region of the fourth active layer (that is, the second region of the ninth active layer) through this via.

In an exemplary implementation, an orthographic projection of the fifth via V5 on the substrate is within a range of an orthographic projection of a first region of a fifth active layer on the substrate, the third insulation layer and the second insulation layer within the fifth via V5 is etched away to expose a surface of the first region of the fifth active layer, and the fifth via V5 is configured to enable a subsequently formed fourth connection electrode to be connected to the first region of the fifth active layer through the via.

In an exemplary implementation, an orthographic projection of the sixth via V6 on the substrate is within a range of an orthographic projection of a second region of the sixth active layer (i.e., a second region of the seventh active layer) on the substrate, the third insulation layer and the second insulation layer within the sixth via V6 are etched away to expose a surface of the second region of the sixth active layer (i.e., the second region of the seventh active layer), and the sixth via V6 is configured to enable a subsequently formed fifth connection electrode to be connected to the second region of the sixth active layer (i.e., the second region of the seventh active layer) through the via.

In an exemplary implementation, an orthographic projection of the seventh via V7 on the substrate is within a range of an orthographic projection of a first region of the seventh active layer on the substrate, the third insulation layer and the second insulation layer within the seventh via V7 is etched off to expose a surface of the first region of the seventh active layer, and the seventh via V7 is configured to enable a subsequently formed second initial signal line to be connected to the first region of the seventh active layer through the via.

In an exemplary implementation, an orthographic projection of the eighth via V8 on the substrate is within a range of an orthographic projection of a first region of the eighth active layer on the substrate, the third insulation layer and the second insulation layer within the eighth via V8 are etched away to expose a surface of the first region of the eighth active layer, and the eighth via V8 is configured to enable a subsequently formed second reference signal line to be connected to the first region of the eighth active layer through the via.

In an exemplary implementation, an orthographic projection of the ninth via V9 on the substrate is within a range of an orthographic projection of a first region of the ninth active layer on the substrate, the third insulation layer and the second insulation layer within the ninth via V9 are etched away to expose a surface of the first region of the ninth active layer, and the ninth via V9 is configured to enable a subsequently formed first reference signal line to be connected to the first region of the ninth active layer through the via.

In an exemplary implementation, an orthographic projection of the tenth via V10 on the substrate is located within a range of an orthographic projection of the first electrode plate connection block 31-1 of the first electrode plate 31 on the substrate, the third insulation layer within the tenth via V10 is etched away to expose a surface of the first electrode plate connection block 31-1, and the tenth via V10 is configured to enable a subsequently formed second connection electrode to be connected to the first electrode plate connection block 31-1 through the via.

In an exemplary implementation mode, an orthographic projection of the eleventh via V11 on the substrate is within a range of an orthographic projection of the second electrode plate connection block 32-2 of the second electrode plate 32 on the substrate, the third insulation layer in the eleventh via V11 is etched away to expose the surface of the second electrode plate connection block 32-2, and the eleventh via V11 is configured to enable a subsequently formed seventh connection electrode to be connected to the second electrode plate connection block 32-2 through the via.

In an exemplary implementation, an orthographic projection of the twelfth via V12 on the substrate is within a range of an orthographic projection of the first gate electrode 21 on the substrate, the third insulation layer in the twelfth via V12 is etched away to expose a surface of the first gate electrode 21, and the twelfth via V12 is configured to enable a subsequently formed fourth scan signal line to be connected to the first gate electrode 21 through the via.

In an exemplary implementation, an orthographic projection of the thirteenth via V13 on the substrate is within a range of an orthographic projection of the second gate electrode 22 on the substrate, the third insulation layer within the thirteenth via V13 is etched away to expose a surface of the second gate electrode 22, and the thirteenth via V13 is configured to enable a subsequently formed second scan signal line to be connected to the second gate electrode 22 through the via.

In an exemplary implementation, an orthographic projection of the fourteenth via V14 on the substrate is within the range of an orthographic projection of the fourth gate electrode 24 on the substrate, the third insulation layer in the fourteenth via V14 is etched away to expose a surface of the fourth gate electrode 24, and the fourteenth via V14 is configured to enable a subsequently formed third scan signal line to be connected to the fourth gate electrode 24 through the via.

In an exemplary implementation mode, an orthographic projection of the fifteenth via V15 on the substrate is within a range of an orthographic projection of the fifth gate electrode 25 on the substrate, the third insulation layer in the fifteenth via V15 is etched away to expose a surface of the fifth gate electrode 25, and the fifteenth via V15 is configured to enable a subsequently formed first light emitting signal line to be connected to the fifth gate electrode 25 through the via.

In an exemplary implementation, an orthographic projection of the sixteenth via V16 on the substrate is within a range of an orthographic projection of the sixth gate electrode 26 on the substrate, the third insulation layer within the sixteenth via V16 is etched away to expose a surface of the sixth gate electrode 26, and the sixteenth via V16 is configured to enable a subsequently formed second light emitting signal line to be connected to the sixth gate electrode 26 through the via.

In an exemplary implementation, an orthographic projection of the seventeenth via V17 on the substrate is within a range of an orthographic projection of the ninth gate electrode 29 on the substrate, the third insulation layer in the seventeenth via V17 is etched away to expose a surface of the ninth gate electrode 29, and the seventeenth via V17 is configured to enable a subsequently formed fifth scan signal line to be connected to the ninth gate electrode 29 through the via.

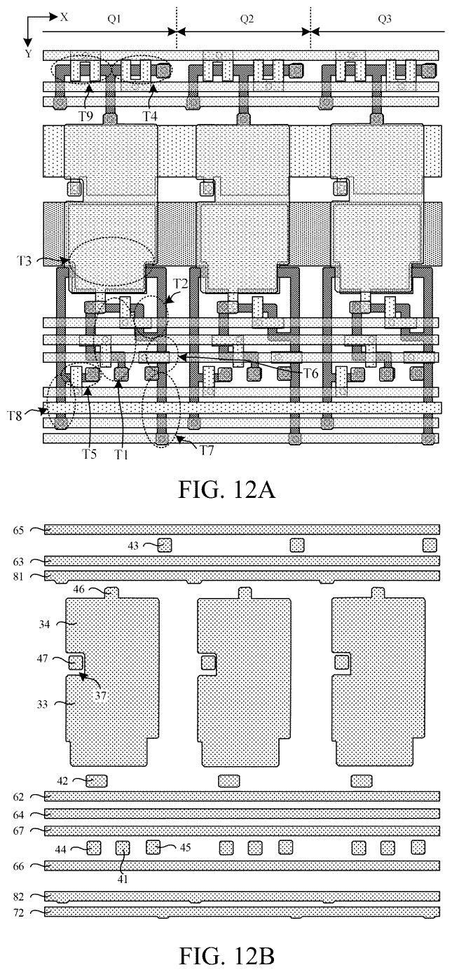

In an exemplary implementation, positions and shapes of the vias in a plurality of circuit units in the first direction X may be substantially the same.
(15) A pattern of a third conductive layer is formed. In an exemplary implementation mode, forming a pattern of the third conductive layer may include: depositing a third conductive thin film on the substrate on which the aforementioned patterns are formed, and patterning the third conductive thin film using a patterning process to form the third conductive layer disposed on the third insulating layer, as shown in FIG. 12A and FIG. 12B, FIG. 12B is a schematic diagram of the third conductive layer in FIG. 12A. In an exemplary implementation, the third conductive layer may be referred to as a first source-drain metal (SD1) layer.

In an exemplary implementation, the third conductive layer pattern of each circuit unit in the display substrate may include a third electrode plate 33 of the first capacitor, a fourth electrode plate 34 of the second capacitor, a first connection electrode 41, a second connection electrode 42, a third connection electrode 43, a fourth connection electrode 44, a fifth connection electrode 45, a sixth connection electrode 46, a seventh connection electrode 47, a second scan signal line 62, a third scan signal line 63, a fourth scan signal line 64, a fifth scan signal line 65, a first light emitting signal line 66, a second light emitting signal line 67, a second initial signal line 72, a first reference signal line 81, and a second reference signal line 82.

In an exemplary implementation, the third electrode plate 33 of the first capacitor may be in a rectangle shape, corner portions of the rectangular shape may be provided with chamfered corners or grooves, an orthographic projection of the third electrode plate 33 on the substrate and an orthographic projection of the first electrode plate 31 on the substrate at least partially overlap, the third electrode plate 33 may serve as the other electrode plate of the first capacitor, and the first electrode plate 31 and the third electrode plate 33 form the first capacitor of the pixel drive circuit.

In an exemplary implementation, the fourth electrode plate 34 of the second capacitor may be in a rectangle shape, corner portions of the rectangular shape may be provided with chamfered corners or grooves, an orthographic projection of the fourth electrode plate 34 on the substrate at least partially overlaps with an orthographic projection of the second electrode plate 32 on the substrate, the fourth electrode plate 34 may serve as the other electrode plate of the second capacitor, and the second electrode plate 32 and the fourth electrode plate 34 form the second capacitor of the pixel drive circuit.

In an exemplary implementation, in at least one circuit unit, the third electrode plate 33 and the fourth electrode plate 34 may form an interconnected integral structure.

In an exemplary implementation, the third electrode plate 33 and the fourth electrode plate 34 of the integral structure may be provided with a groove 37, an orthographic projection of the groove 37 on the substrate at least partially overlaps an orthographic projection of the second electrode plate connection block 32-2 on the substrate, and the groove 37 is configured to accommodate a seventh connection electrode formed subsequently, so that the seventh connection electrode is connected to the second electrode plate connection block 32-2.

In the exemplary implementation, the second scan signal line 62 may be in a straight line shape or a bend line shape in which a main portion extends along the first direction X, and may be located on a side of the third electrode plate 33 away from the fourth electrode plate 34, the second scan signal line 62 is connected to the second gate electrode 22 through the thirteenth via V13, thereby achieving that the second scan signal line 62 is connected to the gate electrode of the second transistor T2, and the second scan signal line 62 can control conduction and disconnection of the second transistor T2.

In an exemplary implementation, the third scan signal line 63 may be in a straight line shape or a bend line shape in which a main portion extends along the first direction X, and may be located on a side of the fourth electrode plate 34 away from the third electrode plate 33, the third scan signal line 63 is connected to a fourth gate electrode 24 through the fourteenth via V14, thereby achieving that the third scan signal line 63 is connected to the gate electrode of the fourth transistor T4, and the third scan signal line 63 can control conduction and disconnection of the fourth transistor T4.

In an exemplary implementation, the fourth scan signal line 64 may be in a straight line shape or a bend line shape in which a main portion extends along the first direction X, and may be located on a side of the second scan signal line 62 away from the third electrode plate 33, the fourth scan signal line 64 is connected to the first gate electrode 21 through the twelfth via V12, thereby achieving that the fourth scan signal line 64 is connected to the gate electrode of the first transistor T1, and the fourth scan signal line 64 can control conduction and disconnection of the first transistor T1.

In the exemplary implementation, the fifth scan signal line 65 may be in a straight line shape or a bend line shape in which a main portion extends along the first direction X, and may be located on a side of the third scan signal line 63 away from a fourth substrate 74, the fifth scan signal line 65 is connected to the ninth gate electrode 29 through the seventeenth via V17, thereby achieving that the fifth scan signal line 65 is connected to the gate electrode of the ninth transistor T9, and the fifth scan signal line 65 can control conduction and disconnection of the ninth transistor T9.

In an exemplary implementation mode, the second scan signal line 62 and the fifth scan signal line 65 may extend to a bezel region and be connected to a same gate drive circuit to achieve output of a same scan signal.

In the exemplary implementation, the first light emitting signal line 66 may be in a straight line shape or a bend line shape in which a main portion extends along the first direction X, the first light emitting signal line 66 may be located on a side of the first scan signal line 61 close to the third electrode plate 33, and the first light emitting signal line 66 is connected to the fifth gate electrode 25 through the fifteenth via V15, thereby achieving that the first light emitting signal line 66 is connected to the gate electrode of the fifth transistor T5, and the first light emitting signal line 66 can control conduction and disconnection of the fifth transistor T5.

In the exemplary implementation, the second light emitting signal line 67 may be in a straight line shape or a bend line shape in which a main portion extends along the first direction X, the second light emitting signal line 67 may be located between the fourth scan signal line 64 and the first light emitting signal line 66, and the second light emitting signal line 67 is connected to the sixth gate electrode 26 through the sixteenth via V16, thereby achieving that the second light emitting signal line 67 is connected to the gate electrode of the sixth transistor T6, and the second light emitting signal line 67 can control conduction and disconnection of the sixth transistor T6.

In the exemplary implementation, the second initial signal line 72 may be in a straight line shape or a bend line shape in which a main portion extends along the first direction X, the second initial signal line 72 may be located on a side of the first scan signal line 61 away from the third electrode plate 33, and the second initial signal line 72 is connected to the first region of the seventh active layer through the seventh via V7, thereby achieving that the second initial signal line 72 is connected to the first electrode of the seventh transistor T7, and the second initial signal line 72 may write a second initial signal to the first electrode of the seventh transistor T7.

In the exemplary implementation, the first reference signal line 81 may be in a straight line shape or a bend line shape in which a main portion extends along the first direction X, the first reference signal line 81 may be located between the third scan signal line 63 and the fourth electrode plate 34, and the first reference signal line 81 is connected to the first region of the ninth active layer through the ninth via V9, thereby achieving that the first reference signal line 81 is connected to the first electrode of the ninth transistor T9, and the first reference signal line 81 may write a first reference signal to the first electrode of the ninth transistor T9.

In an exemplary implementation, the second reference signal line 82 may be in a straight line shape or a bend line shape in which a main portion extends along the first direction X, the second reference signal line 82 may be located between the first light emitting signal line 66 and the second initial signal line 72, and the second reference signal line 82 is connected to the first region of the eighth active layer through the eighth via V8, thereby achieving that the second reference signal line 82 is connected to the first electrode of the eighth transistor T8, and the second reference signal line 82 may write a second reference signal to the first electrode of the eighth transistor T8.

In an exemplary implementation, the third scan signal line 63, the fifth scan signal line 65, and the first reference signal line 81 may be located on a side of the fourth electrode plate 34 away from the third electrode plate 33. Herein, the first reference signal line 81 may be located on a side of the fourth electrode plate 34 away from the third electrode plate 33, the third scan signal line 63 may be located on a side of the first reference signal line 81 away from the fourth electrode plate 34, and the fifth scan signal line 65 may be located on a side of the third scan signal line 63 away from the fourth electrode plate 34.

In an exemplary implementation, the second scan signal line 62, the fourth scan signal line 64, the first light emitting signal line 66, the second light emitting signal line 67, the second initial signal line 72, and the second reference signal line 82 may be located on a side of the third electrode plate 33 away from the fourth electrode plate 34. Herein, the second scan signal line 62 may be located on a side of the third electrode plate 33 away from the fourth electrode plate 34, the fourth scan signal line 64 may be located on a side of the second scan signal line 62 away from the third electrode plate 33, the second light emitting signal line 67 may be located on a side of the fourth scan signal line 64 away from the third electrode plate 33, the first light emitting signal line 66 may be located on a side of the second light emitting signal line 67 away from the third electrode plate 33, the second reference signal line 82 may be located on a side of the first light emitting signal line 66 away from the third electrode plate 33, and the second initial signal line 72 may be located on a side of the second reference signal line 82 away from the third electrode plate 33.

In an exemplary implementation, the first connection electrode 41 may be in a block shape (e.g., a rectangle), and may be arranged between the first light emitting signal line 66 and the second light emitting signal line 67, the first connection electrode 41 is connected to the first region of the first active layer through the first via V1. In an exemplary implementation, the first connection electrode 41 is configured to be connected to a first initial signal line subsequently formed.

In an exemplary implementation, the second connection electrode 42 may be in a block shape (e.g. rectangular) and may be arranged between the third electrode plate 33 and the second scan signal line 62, the first terminal of the second connection electrode 42 is connected to the second region of the first active layer (also the first region of the second active layer) through the second via V2, and the second terminal of the second connection electrode 42 is connected to the first electrode plate connection block 31-1 through the tenth via V10. Because the first electrode plate connection block 31-1 is connected to the first electrode plate 31, and the first electrode plate 31 is the gate electrode of the third transistor T3, thus the second connection electrode 42 enables that the second electrode of the first transistor T1, the first electrode of the second transistor T2, the gate electrode of the third transistor T3, and the first terminal of the first capacitor have the same potential, such that the first node N1 of the pixel drive circuit is formed.

In an exemplary implementation, the third connection electrode 43 may be in a block shape (e.g. rectangular), and may be arranged between the third scan signal line 63 and the fifth scan signal line 65, and the third connection electrode 43 is connected to the first region of the fourth active layer through the third via V3. In an exemplary implementation mode, the third connection electrode 43 is configured to be connected to a data signal line formed subsequently.

In an exemplary implementation, the fourth connection electrode 44 may be in a block shape (e.g. rectangular), and may be arranged between the first light emitting signal line 66 and the second light emitting signal line 67, and the fourth connection electrode 44 is connected to the first region of the fifth active layer through the fifth via V5. In an exemplary implementation, the fourth connection electrode 44 is configured to be connected to a first power supply line formed subsequently.

In an exemplary implementation, the fifth connection electrode 45 may be in a block shape (e.g. rectangular) and may be arranged between the first light emitting signal line 66 and the second light emitting signal line 67, and the fifth connection electrode 45 is connected to the second region of the sixth active layer (also the second region of the seventh active layer) through the sixth via V6. In an exemplary implementation, the fifth connection electrode 45 is configured to be connected to an anode connection electrode to be formed subsequently.

In the exemplary implementation, in the at least one circuit unit, the first connection electrode 41 may be arranged on a side of the fourth connection electrode 44 in the first direction, and the fifth connection electrode 45 may be arranged on a side of the first connection electrode 41 in the first direction X.

In the exemplary implementation, the sixth connection electrode 46 may be in a block shape (e.g. rectangular), and may be arranged on a side of the fourth electrode plate 34 away from the third electrode plate 33 and connected to the fourth electrode plate 34, and the sixth connection electrode 46 is connected to the second region of the fourth active layer (also the second region of the ninth active layer) through the fourth via V4.

In an exemplary implementation, the sixth connection electrode 46 and the fourth electrode plate 34 may form an interconnected integral structure. Because the third electrode plate 33 and the fourth electrode plate 34 are of an interconnected integral structure, the sixth connection electrode 46 enables that the second electrode of the fourth transistor T4, the second electrode of the ninth transistor T9, the third electrode plate 33 of the first capacitor, and the fourth electrode plate 34 of the second capacitor have the same potential, forming the fifth node N5 of the pixel drive circuit.

In the exemplary implementation, the seventh connection electrode 47 may be in a block shape (e.g., rectangular) and may be arranged in the groove 37, and the seventh connection electrode 47 is connected to the second electrode plate connection block 32-2 through the eleventh via V11. In an exemplary implementation, the seventh connection electrode 47 is configured to be connected to a first power supply line formed subsequently.

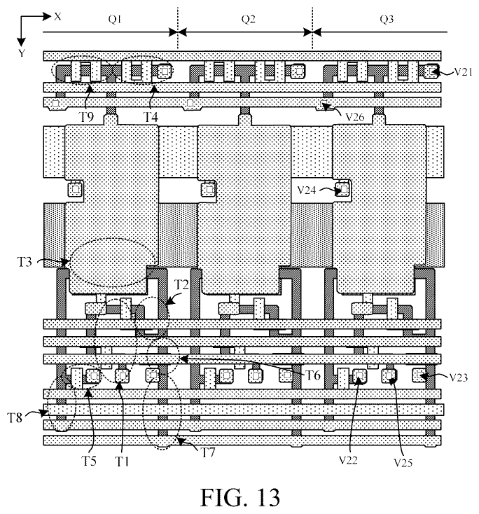

In an exemplary implementation, positions and shapes of the third conductive layers in a plurality of circuit units in the first direction X may be substantially the same.
(16) Forming a pattern of a fourth insulation layer. In an exemplary implementation, forming the pattern of a fourth insulation layer may include: depositing a fourth insulation thin film on the substrate on which the aforementioned patterns are formed, patterning the fourth insulation thin film through a patterning process, forming a fourth insulation layer that covers the third conductive layer, wherein a plurality of vias are arranged in each circuit unit, as shown in FIG. 13.

In an exemplary implementation, the plurality of vias for each circuit unit in the display substrate at least include: a twenty-first via V21, a twenty-second via V22, a twenty-third via V23, a twenty-fourth via V24, a twenty-fifth via V25, and a twenty-sixth via V26.

In an exemplary implementation, an orthographic projection of the twenty-first via V21 on the substrate is located within a range of an orthographic projection of the third connection electrode 43 on the substrate, the fourth insulation layer within the twenty-first via V21 is removed to expose a surface of the third connection electrode 43, and the twenty-first via V21 is configured to enable a subsequently formed data signal line to be connected to the third connection electrode 43 through the via.

In an exemplary implementation, an orthographic projection of the twenty-second via V22 on the substrate is located within a range of an orthographic projection of the fourth connection electrode 44 on the substrate, the fourth insulation layer within the twenty-second via V22 is removed to expose a surface of the fourth connection electrode 44, and the twenty-second via V22 is configured to enable a subsequently formed first power supply line to be connected to the fourth connection electrode 44 through the via.

In an exemplary implementation mode, an orthographic projection of the twenty-third via V23 on the substrate is located within a range of an orthographic projection of the fifth connection electrode 45 on the substrate, the fourth insulation layer within the twenty-third via V23 is removed to expose a surface of the fifth connection electrode 45, and the twenty-third via V23 is configured to enable a subsequently formed anode connection electrode to be connected to the fifth connection electrode 45 through the via.

In an exemplary implementation mode, an orthographic projection of the twenty-fourth via 24 on the substrate is located within a range of an orthographic projection of the seventh connection electrode 47 on the substrate, the fourth insulation layer within the twenty-fourth via V24 is removed to expose a surface of the seventh connection electrode 47, and the twenty-fourth via V24 is configured to enable a subsequently formed first power supply line to be connected to the seventh connection electrode 47 through the via.

In an exemplary implementation, an orthographic projection of the twenty-fifth via V25 on the substrate is within a range of an orthographic projection of the first connection electrode 41 on the substrate, the fourth insulation layer in the twenty-fifth via V25 is removed to expose a surface of the first connection electrode 41, and the twenty-fifth via V25 is configured to enable a subsequently formed first initial signal line to be connected to the first connection electrode 41 through the twenty-fifth via V25.

In an exemplary implementation, an orthographic projection of the twenty-sixth via V26 on the substrate is within a range of an orthographic projection of the first reference signal line 81 on the substrate, the fourth insulation layer within the twenty-sixth via V26 is removed to expose a surface of the first reference signal line 81, and the twenty-sixth via V26 is configured to enable a subsequently formed first reference connection line to be connected to the first reference signal line 81 through the via.

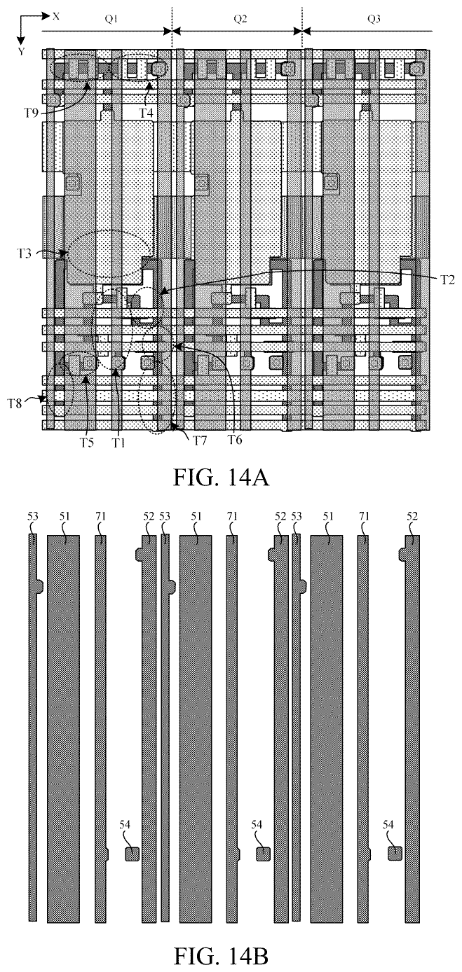

In an exemplary implementation, positions and shapes of the vias in a plurality of circuit units in the first direction X may be substantially the same.
(17) A pattern of a fourth conductive layer is formed. In an exemplary implementation, forming a pattern of a fourth conductive layer pattern may include: depositing a fourth conductive film on a substrate on which the aforementioned patterns are formed, patterning the fourth conductive film using a patterning process to form a fourth conductive layer arranged on the fourth insulation layer, as shown in FIGS. 14A and 14B, FIG. 14B is a schematic diagram of the fourth conductive layer in FIG. 14A. In an exemplary implementation, the fourth conductive layer may be referred to as a second source-drain metal (SD2) layer.

In an exemplary implementation, each of patterns of fourth conductive layers of a plurality of circuit units in the display substrate may include: a first power supply line 51, a data signal line 52, a first reference connection line 53, an anode connection electrode 54 and a first initial signal line 71.

In the exemplary implementation, the first power supply line 51, the data signal line 52, the first reference connection line 53, and the first initial signal line 71 may be in a straight line shape or a bend line shape in which a main portion extends along the second direction Y, the first power supply line 51 may be located on a side of the first reference connection line 53 in the first direction X, the first initial signal line 71 may be located on a side of the first power supply line 51 in the first direction X, and the data signal line 52 may be located on a side of the first initial signal line 71 in the first direction X.

In an exemplary implementation, the first power supply line 51 may be in a straight line shape or a bend line shape in which a main portion extending along the second direction Y. On one hand, the first power supply line 51 is connected to the fourth connection electrode 44 through the twenty-second via V22, and on the other hand, the first power supply line 51 is connected to the seventh connection electrode 47 through the twenty-fourth via V24. The fourth connection electrode 44 is connected to the first region of the fifth active layer through a via, the seventh connection electrode 47 is connected to the second electrode plate connection block 32-2 through a via, and the second electrode plate connection block 32-2 is connected to the second electrode plate 32. Therefore, a connection of the first power supply line 51 with the first electrode of the fifth transistor T5 and the second electrode plate 32 of the second capacitor is achieved. The first power supply line 51 can write a first power supply signal to the first electrode of the fifth transistor T5 and the first terminal of the second capacitor.

In an exemplary implementation, an orthographic projection of the first power supply line 51 on the substrate is overlapped, at least partially, with an orthographic projection of the second connection electrode 42 on the substrate. Because the second connection electrode 42 serves as the first node N1 in the pixel drive circuit, the first power supply line 51 which is at a constant voltage can effectively shield an influence of other signals in the pixel drive circuit on the first node N1, thereby avoiding an influence of other signals (such as the data voltage jump) on a potential at the first node N1 in the pixel drive circuit, and improving the display effect.

In the exemplary implementation, the data signal line 52 may be in a shape of a straight line or a bend line in which a main portion extends along the second direction Y, and the data signal line 52 is connected to the third connection electrode 43 through the twenty-first via V21. Because the third connection electrode 43 is connected to the first region of the fourth active layer through a via, writing of the data signal to the first electrode of the fourth transistor T4 by the data signal line 52 is achieved.

In the exemplary implementation, the first reference connection line 53 may be in a straight line shape or a bend line shape in which a main portion extends along the second direction Y, and the first reference connection line 53 is connected to the first reference signal line 81 through the twenty-sixth via V26, thereby achieving a mutual connection between the first reference signal line 81 in which a main portion extends along the first direction X and the first reference connection line 53 in which the main portion extends along the second direction Y, so that the first reference signal line 81 and the first reference connection line 53 form a mesh-shaped network communication structure for transmitting a first reference signal on the display substrate, which not only effectively reduces a resistance of the first reference signal line and reduces a voltage drop of the first reference signal, but also effectively improves a uniformity of the first reference signal in the display substrate, effectively improves a uniformity of the display, and improves display attribute and display quality.

In an exemplary implementation, the anode connection electrode 54 may be in a block shape (e.g. rectangular), and the anode connection electrode 54 is connected to the fifth connection electrode 45 through the twenty-third via V23. Because the fifth connection electrode 45 is connected to the second region of the sixth active layer (also the second region of the seventh active layer) through a via, it is achieved that the anode connection electrode 54 is connected to the second electrode of the sixth transistor T6 and the second electrode of the seventh transistor T7. In an exemplary implementation, the anode connection electrode 54 is configured to connect with the anode formed later, thereby the pixel drive circuit can drive a light emitting device.

In the exemplary implementation, a shape of the first initial signal line 71 may be a straight line or a bend line in which a main portion extends in the second direction Y, and the first initial signal line 71 is connected to the first connection electrode 41 through the twenty-fifth via V25, thereby achieving that the first initial signal line 71 writes a first initial signal to the first electrode of the first transistor T1.

In an exemplary implementation, the first power supply line 51, the data signal line 52, the first reference connection line 53, and the first initial signal line 71 may be designed with equal width or may be designed with non-equal width, which not only facilitates the layout of the pixel structure, but also reduces the parasitic capacitance between the signal lines.

In the exemplary implementation, because the first electrode plate 31 (the first terminal of the first capacitor) of the first capacitor has a potential of the first node N1, and the third electrode plate 33 (the second terminal of the first capacitor) of the first capacitor has a potential of the fifth node N5, the first electrode plate 31 and the third electrode plate 33 form the first capacitor.

In the exemplary implementation, because the second electrode plate 32 (the first terminal of the second capacitor) of the second capacitor has a potential of the first power supply line 51, and the fourth electrode plate 34 (the second terminal of the second capacitor) of the second capacitor has a potential of the fifth node N5, the second electrode plate 32 and the fourth electrode plate 34 form the second capacitor.

The present disclosure uses the first conductive layer and the third conductive layer to form a first capacitor and a second capacitor, and the third electrode plate and the fourth electrode plate form an interconnected integral structure, which effectively increases the capacitance value of the first capacitor and the second capacitor, and reduces the occupied area. In an exemplary implementation, positions and shapes of the fourth conductive layers among a plurality of circuit units in the first direction X may be substantially the same.

In an exemplary implementation, a subsequent preparation process may include: forming a pattern of a planarization layer, the planarization layer is provided with an anode via, an orthographic projection of the anode via on the substrate is within a range of an orthographic projection of the anode connection electrode on the substrate. The planarization layer within the anode via is removed to expose a surface of the anode connection electrode, and the anode via is configured to enable a subsequently formed anode to be connected to the anode connection electrode through the anode via.

So far, a drive circuit layer has been manufactured on the substrate. In an exemplary implementation, after the drive circuit layer is manufactured, a light emitting structure layer and an encapsulation structure layer may be sequentially manufactured on the drive circuit layer, which is not repeated here.

In an exemplary implementation, the substrate may be a flexible substrate, or a rigid substrate. The rigid substrate may be made of, but is not limited to, one or more of glass and quartz. The flexible substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the substrate, and a material of the semiconductor layer may be amorphous silicon (a-si).

In an exemplary implementation, the first conductive layer, the third conductive layer, and the fourth conductive layer may be made of a metal material, such as any one or more of Silver (Ag), Copper (Cu), Aluminum (Al) and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology.

In the exemplary implementation, in the above-described preparation process, while the pixel drive circuit is formed in the display region, a gate drive circuit may be synchronously formed in a bezel region and a data transmission line may be synchronously formed in a bonding region.

In an exemplary implementation, a scan output line of the gate drive circuit in the bezel region is connected to a scan signal line in the display region. A plurality of scan output lines in the bezel region may all be located in the first conductive layer, and are connected to a plurality of scan signal lines located in the third conductive layer in the display region through a jumper manner. Alternatively, the plurality of scan output lines in the bezel region may be alternately located in the first conductive layer and the fourth conductive layer, and are connected to the plurality of scan signal lines located in the third conductive layer in the display region through a jumper manner.

In an exemplary implementation, a data transmission line in the bonding region is connected to a data signal line in the display region. A plurality of data transmission lines in the bonding region may all be located in the first conductive layer, and are connected to a plurality of data signal lines located in the fourth conductive layer in the display region through a jumper manner. Alternatively, a plurality of data transmission lines in the bonding region may be alternately located in the barrier shield metal layer and the first conductive layer, and are connected to a plurality of data signal lines located in the fourth conductive layer in the display region by a jumper manner. Alternatively, the plurality of data transmission lines of the bonding region may alternately be located in the first conductive layer and the third conductive layer, or the plurality of data transmission lines of the bonding region may be alternately located in the first conductive layer and the fourth conductive layer, the present disclosure is not limited herein.

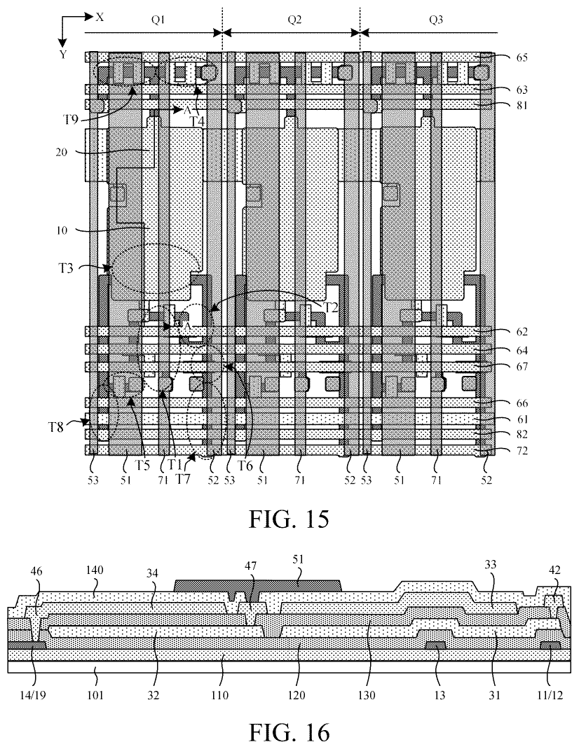

FIG. 15 is a schematic diagram of a planar structure of yet another display substrate according to an exemplary embodiment of the present disclosure, and FIG. 16 is a sectional view taken along an A-A direction in FIG. 15. A main structure of the display substrate according to the present embodiment is substantially the same as that of the display substrate shown in FIG. 6 and FIG. 7, except that the display substrate according to the present embodiment is not provided with a barrier shield metal layer.

As shown in FIGS. 15 and 16, in an exemplary implementation, on a plane perpendicular to the display substrate, the display substrate may include: a first insulation layer 110 arranged on the substrate 101, a semiconductor layer arranged on a side of the first insulation layer 110 away from the substrate 101, a second insulation layer 120 arranged on a side of the semiconductor layer away from the substrate 101, a first conductive layer (GATE 1) arranged on a side of the second insulation layer 120 away from the substrate 101, a third insulation layer 130 arranged on a side of the first conductive layer away from the substrate 101, a third conductive layer (SD1) arranged on a side of the third insulation layer 130 away from the substrate 101, a fourth insulation layer 140 arranged on a side of the third conductive layer away from the substrate 101, and a fourth conductive layer (SD2) arranged on a side of the fourth insulation layer 140 away from the substrate 101.

In an exemplary implementation, the semiconductor layer may at least include: a first active layer 11, a second active layer 12, a third active layer 13, a fourth active layer 14, and a ninth active layer 19. The first conductive layer may at least include a first electrode plate 31 and a second electrode plate 32. The third conductive layer may at least include: a third electrode plate 33, a fourth electrode plate 34, a second connection electrode 42, a sixth connection electrode 46, a seventh connection electrode 47. An orthographic projection of the third electrode plate 33 on the substrate at least partially overlaps with an orthographic projection of the first electrode plate 31 on the substrate, an orthographic projection of the fourth electrode plate 34 on the substrate at least partially overlaps with an orthographic projection of the second electrode plate 32 on the substrate, the second connection electrode 42 is connected to the first electrode plate 31 through a via, the sixth connection electrode 46 is connected to the fourth active layer 14 and the ninth active layer 19 through a via, and the seventh connection electrode 47 is connected to the second electrode plate 32 through a via. The fourth conductive layer may at least include a first power supply line 51, the first power supply line 51 is connected to the seventh connection electrode 47 through a via.

In an exemplary implementation, the first conductive layer may further include a first scan signal line 61 and gate electrodes of a plurality of transistors. The third conductive layer may further include a second scan signal line 62, a third scan signal line 63, a fourth scan signal line 64, a fifth scan signal line 65, a first light emitting signal line 66, a second light emitting signal line 67, a second initial signal line 72, a first reference signal line 81, a second reference signal line 82, and a plurality of connection electrodes. The fourth conductive layer may further include a data signal line 52, a first reference connection line 53, and a first initial signal line 71.

In the exemplary implementation, the present embodiment shows a preparation process of the display substrate substantially the same as that of the aforementioned embodiments, except that there is no operation of forming a barrier shield metal layer.

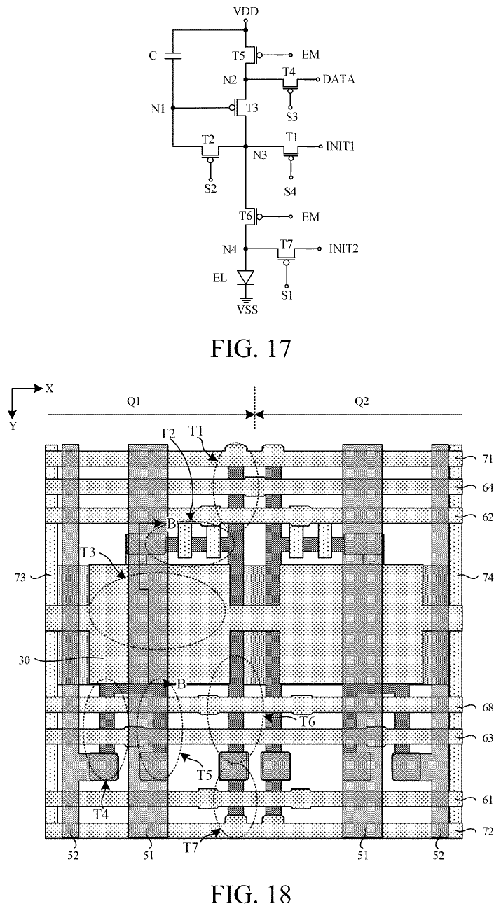

FIG. 17 is a diagram of an equivalent circuit of another pixel drive circuit according to an exemplary embodiment of the present disclosure. As shown in FIG. 17, the pixel drive circuit of an exemplary embodiment of the present disclosure may be of a 7T1C structure, and may include seven transistors (a first transistor T1 to a seventh transistor T7) and one storage capacitor C. The pixel drive circuit is respectively connected to nine signal lines (a first scan signal line S1, a second scan signal line S2, a third scan signal line S3, a fourth scan signal line S4, a light emitting signal line EM, a first initial signal line INIT1, a second initial signal line INIT2, a data signal line DATA and a first power supply line VDD).

In an exemplary implementation, the pixel drive circuit may include a first node N1, a second node N2, a third node N3, and a fourth node N4. Herein, the first node N1 is connected to a first electrode of the second transistor T2, a gate electrode of the third transistor T3 and a first terminal of the storage capacitor C, respectively, the second node N2 is connected to a first electrode of the third transistor T3, a second electrode of the fourth transistor T4 and a second electrode of the fifth transistor T5, respectively, the third node N3 is connected to a second electrode of the first transistor, a second electrode of the second transistor T2, a second electrode of the third transistor T3 and a first electrode of the sixth transistor T6, respectively, and the fourth node N4 is respectively connected to a second electrode of the sixth transistor T6 and a second electrode of the seventh transistor T7.

In an exemplary implementation, the first terminal of the storage capacitor C is connected to the first node N1, and a second terminal of the storage capacitor C is connected to the first power supply line VDD.

In an exemplary implementation, the first transistor T1 may be referred to as a first initialization transistor, a gate electrode of the first transistor T1 is connected to the fourth scan signal line S4, a first electrode of the first transistor T1 is connected to the first initial signal line INIT1, and the second electrode of the first transistor is connected to the first node N1.

In an exemplary implementation, the second transistor T2 may be referred to as a compensation transistor, a gate electrode of the second transistor T2 is connected to the second scan signal line S2, the first electrode of the second transistor T2 is connected to the first node N1, and the second electrode of the second transistor T2 is connected to the third node N3.

In an exemplary implementation, the gate electrode of the third transistor T3 is connected to the first node N1, the first electrode of the third transistor T3 is connected to the second node N2, and the second electrode of the third transistor T3 is connected to the third node N3.

In an exemplary implementation mode, the fourth transistor T4 may be referred to as a data writing transistor, a gate electrode of the fourth transistor T4 is connected to the third scan signal line S3, a first electrode of the fourth transistor T4 is connected to a data signal line DATA, and the second electrode of the fourth transistor T4 is connected to the second node N2. In an exemplary implementation, the fifth transistor T5 may be referred to as a first light emitting control transistor, a gate electrode of the fifth transistor T5 is connected to the light emitting signal line EM, a first electrode of the fifth transistor T5 is connected to the first power supply line VDD, and the second electrode of the fifth transistor T5 is connected to the second node N2.

In an exemplary implementation, the sixth transistor T6 may be referred to as a second light emitting control transistor, a gate electrode of the sixth transistor T6 is connected to the light emitting signal line EM, the first electrode of the sixth transistor T6 is connected to the third node N3, and the second electrode of the sixth transistor T6 is connected to the fourth node N4.

In an exemplary implementation, the seventh transistor T7 may be referred to as a second initialization transistor, a gate electrode of the seventh transistor T7 is connected to the first scan signal line S1, a first electrode of the seventh transistor T7 is connected to the second initial signal line INIT2, and the second electrode of the seventh transistor T7 is connected to the fourth node N4.

In an exemplary implementation, a first electrode of a light emitting device EL is connected to the fourth node N4, and a second electrode of the light emitting device EL is connected to the second power supply line VSS. The light emitting device EL may be an OLED including a first electrode (anode), an organic light emitting layer, and a second electrode (cathode) which are stacked, or may be a QLED including a first electrode (anode), a quantum dot light emitting layer, and a second electrode (cathode) which are stacked.

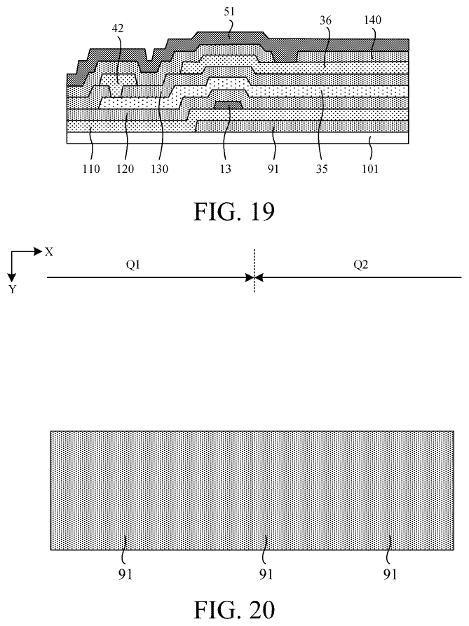

FIG. 18 is a schematic diagram of a planar structure of another display substrate according to an exemplary embodiment of the present disclosure, illustrating a structure of a pixel drive circuit in two circuit units (a first circuit unit Q1 and a second circuit unit Q2) in the display substrate, and FIG. 19 is a sectional view in the B-B direction in FIG. 18. As shown in FIGS. 18 and 19, the pixel drive circuit in at least one circuit unit may at least include a storage capacitor and a plurality of transistors, the plurality of transistors may include a first transistor Tl as a first initialization transistor, a second transistor T2 as a compensation transistor, a third transistor T3 as a drive transistor, a fourth transistor T4 as a data writing transistor, a fifth transistor T5 as a first light emitting control transistor, a sixth transistor T6 as a second light emitting control transistor, and a seventh transistor T7 as a second initialization transistor. The storage capacitor may include a fifth electrode plate 35 and a sixth electrode plate 36, and an orthographic projection of the sixth electrode plate 36 on the substrate at least partially overlaps with an orthographic projection of the fifth electrode plate 35 on the substrate.

In an exemplary implementation, a gate electrode of the first transistor T1 is connected to the fourth scan signal line 64, a first electrode of the first transistor T1 is connected to the first initial signal line 71, and a second electrode of the first transistor T1 is connected to a second electrode of the second transistor T2, a second electrode of the third transistor T3, and a first electrode of the sixth transistor T6, respectively. A gate electrode of the second transistor T2 is connected to the second scan signal line 62, and a first electrode of the second transistor T2 is connected to the fifth electrode plate 35 through the second connection electrode 42. A gate electrode of the third transistor T3 may serve as the fifth electrode plate 35, and a first electrode of the third transistor T3 is connected to a second electrode of the fourth transistor T4 and a second electrode of the fifth transistor T5, respectively. A gate electrode of the fourth transistor T4 is connected to the third scan signal line 63, and a first electrode of the fourth transistor T4 is connected to the data signal line 52. A gate electrode of the fifth transistor T5 is connected to the light emitting signal line 68, and a first electrode of the fifth transistor T5 is connected to the first power supply line 51. A gate electrode of the sixth transistor T6 is connected to the light emitting signal line 68, and a second electrode of the sixth transistor T6 is connected to a second electrode of the seventh transistor T7. A gate electrode of the seventh transistor T7 is connected to a first scan signal line 61, and a first electrode of the seventh transistor T7 is connected to a second initial signal line 72.

In an exemplary implementation, the first scan signal line 61, the second scan signal line 62, the third scan signal line 63, the fourth scan signal line 64, the light emitting signal line 68, the first initial signal line 71 and the second initial signal line 72 may be in a shape of a straight line or a bend line in which a main portion extends in the first direction X, and the first power supply line 51 and the data signal line 52 may be in a shape of a straight line or a bend line in which a main portion extends in the second direction Y.

In an exemplary implementation, an initial connection line 73 may be included in the at least one circuit unit. The first initial connection line 73 may be in a straight line shape or a bend line shape in which a main portion extends along the second direction Y, and is connected to the first initial signal line 71, thereby achieving the mutual connection between the first initial signal line 71 in which a main portion extends along the first direction X and the first initial connection line 73 in which a main portion extends along the second direction Y, so that the first initial signal line 71 and the first initial connection line 73 form a mesh-shaped network communication structure for transmitting a first initial signal on the display substrate.

In an exemplary implementation, at least one circuit unit may further include a second initial connection line 74. The second initial connection line 74 may be in a straight line shape or a bend line shape in which a main portion extends along the second direction Y, and is connected to the second initial signal line 72, thereby achieving the mutual connection between the second initial signal line 72 in which a main portion extends along the first direction X and the second initial connection line 74 in which the main portion extends along the second direction Y, so that the second initial signal line 72 and the second initial connection line 74 form a mesh-shaped network communication structure for transmitting a second initial signal on the display substrate.

In an exemplary implementation, on a plane perpendicular to the display substrate, the display substrate may include: a barrier shield metal layer (BSM) arranged on the substrate 101, a first insulation layer 110 arranged on a side of the barrier shield metal layer away from the substrate 101, a semiconductor layer arranged on a side of the first insulation layer 110 away from the substrate 101, a second insulation layer 120 arranged on a side of the semiconductor layer away from the substrate 101, a first gate metal layer (GATE 1) arranged on a side of the second insulation layer 120 away from the substrate 101, a third insulation layer 130 arranged on a side of the first conductive layer away from the substrate 101, a first source drain metal layer (SD1) arranged on a side of the third insulation layer 130 away from the substrate 101, a fourth insulation layer 140 arranged on a side of the third conductive layer away from the substrate 101, and a second source-drain metal layer (SD2) arranged on a side of the fourth insulation layer 140 away from the substrate 101.

In an exemplary implementation, the fifth electrode plate 35 of the storage capacitor 30 may be arranged in the first gate metal layer, the sixth electrode plate 36 of the storage capacitor 30 may be arranged in the first source drain metal layer, and an orthographic projection of the fifth electrode plate 35 on the substrate at least partially overlaps with an orthographic projection of the sixth electrode plate 36 on the substrate.

In an exemplary implementation, a first gate electrode of the first transistor T1 may be arranged in the first gate metal layer, the fourth scan signal line 64 may be arranged in the first source drain metal layer, and the fourth scan signal line 64 may be connected to the first gate electrode of the first transistor T1 through a first gate via.

In an exemplary implementation, in the first direction X, the first gate electrodes in two partially adjacent circuit units may be an interconnected integral structure.

In an exemplary implementation, in the first direction X, two partially adjacent circuit units share a same first gate via by which the first gate electrode is connected to a fourth scan signal line 64.

In an exemplary implementation, a second gate electrode of the second transistor T2 may be arranged in the first gate metal layer, the second scan signal line 62 may be arranged in the first source drain metal layer, and the second scan signal line 62 may be connected to the second gate electrode of the second transistor T2 through a via.

In an exemplary implementation, a fourth gate electrode of the fourth transistor T4 may be arranged in the first gate metal layer, the third scan signal line 63 may be arranged in the first source drain metal layer, and the third scan signal line 63 may be connected to the fourth gate electrode of the fourth transistor T4 through a via.

In an exemplary implementation, a fifth gate electrode of the fifth transistor T5 may be arranged in the first gate metal layer, the light emitting signal line 68 may be arranged in the first source drain metal layer, and the light emitting signal line 68 may be connected to the fifth gate electrode of the fifth transistor T5 through a via.

In an exemplary implementation, a sixth gate electrode of the sixth transistor T6 may be arranged in the first gate metal layer, the light emitting signal line 68 may be arranged in the first source drain metal layer, and the light emitting signal line 68 may be connected to the sixth gate electrode of the sixth transistor T6 through a via.

In an exemplary implementation, in the at least one circuit unit, the fifth gate electrode and the sixth gate electrode may form an interconnected integral structure.

In an exemplary implementation, in at least one circuit unit, the fifth gate electrode and the sixth gate electrode may share a same via connected to the light emitting signal line 68, i.e., the light emitting signal line 68 is simultaneously connected to the fifth gate electrode of the fifth transistor T5 through the same via.

In an exemplary implementation, in the first direction X, the sixth gate electrodes in the two partially adjacent circuit units may form an interconnected integral structure.

In an exemplary implementation, in the first direction X, the fifth gate electrodes and the sixth gate electrodes in two partially adjacent circuit units may form an interconnected integral structure.

In an exemplary implementation, a seventh gate electrode of the seventh transistor T7 may be arranged in the first gate metal layer, the first scan signal line 61 may be arranged in the first source drain metal layer, and the first scan signal line 61 may be connected to the seventh gate electrode of the seventh transistor T7 through a via.

In an exemplary implementation, in the first direction X, the seventh gate electrodes in two partially adjacent circuit units may form an interconnected integral structure.

In an exemplary implementation, the first initial connection line 73 and the second initial connection line 74 may be arranged in the first gate metal layer, and the first initial signal line 71 and the second initial signal line 72 may be arranged in the first source drain metal layer.

As shown in FIG. 19, in an exemplary implementation, the barrier shield metal layer may at least include a barrier shield electrode 91, the semiconductor layer may at least include a third active layer 13, and the first gate metal layer (first conductive layer) may at least include a fifth electrode plate 35. The first source drain metal layer (third conductive layer) may at least include a sixth electrode plate 36 and a second connection electrode 42, and the second connection electrode 42 is connected to the fifth electrode plate 35 through a via. The second source drain metal layer (the fourth conductive layer) may at least include a first power supply line 51, and the first power supply line 51 is connected to the sixth electrode plate 36 through a via.

In an exemplary implementation mode, taking two circuit units (the first circuit unit Q1 and the second circuit unit Q2) as an example, a preparation process of the display substrate according to this embodiment may include the following operations.
(21) Forming a pattern of a barrier shield metal layer. In an exemplary implementation, forming a pattern of a barrier shield metal layer may include: depositing a barrier shield metal film on a substrate, patterning the barrier shield metal film by a patterning process, and forming a barrier shield metal layer (BSM) arranged on the substrate, as shown in FIG. 20.

In an exemplary implementation, the barrier shield metal layer of each circuit unit in the display substrate may at least include a barrier shield electrode 91.

In the exemplary implementation, a shape of the barrier shield electrode 91 may be a block shape (e.g. a rectangle), and the barrier shield electrode 91 is configured as a shielding layer of the third transistor T3 to shield light on the third transistor T3, reduce light intensity irradiated on the third transistor T3, reduce leakage current of the third transistor T3, and thereby reduce an influence of light on the characteristics of the third transistor T3.

In an exemplary implementation, a barrier shield electrode 91 in the present circuit unit and a barrier shield electrode 91 in the adjacent circuit unit in the first direction X may form an interconnected integral structure to form an barrier shield line extending along the first direction X.

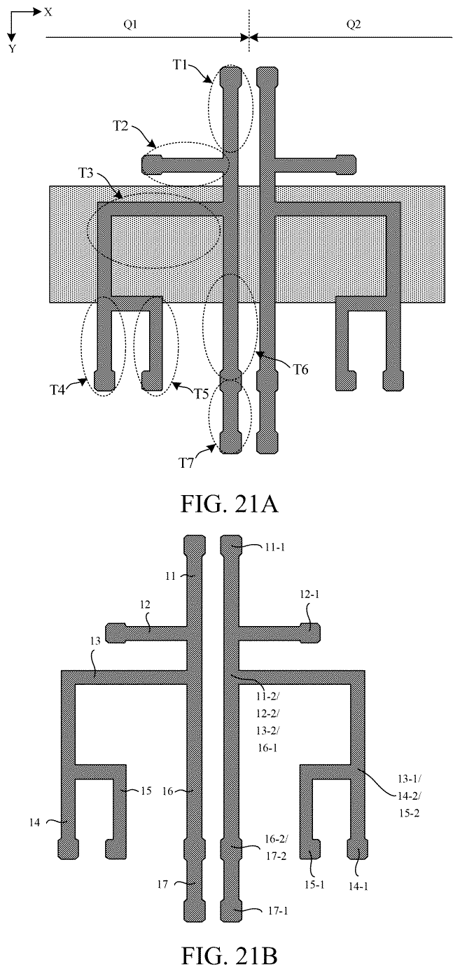

In an exemplary implementation, the barrier shield metal layers of adjacent circuit units in the first direction X may be substantially mirror symmetrical with respect to a unit reference line, and the unit reference line is a straight line located between the adjacent circuit units and extending along the second direction Y.
(22) Forming a pattern of a semiconductor layer. In an exemplary implementation mode, forming a pattern of a semiconductor layer may include: on the substrate on which the aforementioned pattern is formed, sequentially depositing a first insulation thin film and a semiconductor thin film, patterning the semiconductor thin film by a patterning process to form a first insulation layer covering the barrier shield metal layer, and a semiconductor layer arranged on the first insulation layer, as shown in FIGS. 21A and 21B, FIG. 21B is a schematic diagram of the semiconductor layer in FIG. 21A.

In an exemplary implementation, the semiconductor layer of each circuit unit in the display substrate may at least include: a first active layer 11 of the first transistor T1, a second active layer 12 of the second transistor T2, a third active layer 13 of the third transistor T3, a fourth active layer 14 of the fourth transistor T4, a fifth active layer 15 of the fifth transistor T5, a sixth active layer 16 of the sixth transistor T6, and a seventh active layer 17 of the seventh transistor T7. And the first active layer 11 to the seventh active layer 17 may form an interconnected integral structure.

In an exemplary implementation, in the second direction Y, the first active layer 11 and the second active layer 12 may be located on a side of the third active layer 13 of a present circuit unit in an opposite direction of the second direction Y, and the fourth active layer 14, the fifth active layer 15, the sixth active layer 16, and the seventh active layer 17 may be located on a side of the third active layer 13 in the second direction Y.

In an exemplary implementation, the first active layer 11, the second active layer 12, the fourth active layer 14, the sixth active layer 16, and the seventh active layer 17 may be in an “I” shape, and the third active layer 13 and the fifth active layer 15 may be in an “L” shape.

In the exemplary implementation, an orthographic projection of the third active layer 13 on the substrate at least partially overlaps with an orthographic projection of the barrier shield electrode 91 on the substrate, so that the barrier shield electrode 91 can shield the third transistor T3, reduce light intensity irradiated on the third transistor T3, reduce leakage current of the third transistor T3, and thereby reducing an influence of light on the characteristics of the third transistor T3.

In an exemplary implementation, an active layer of each transistor may include a first region, a second region, and a channel region located between the first region and the second region. In an exemplary implementation, a second region 11-2 of the first active layer, a second region 12-2 of the second active layer, a second region 13-2 of the third active layer, and a first region 16-1 of the sixth active layer may be connected to each other, and the second region 13-2 of the third active layer may simultaneously serve as a second region 11-2 of the first active layer, the second region 12-2 of the second active layer, and the first region 16-1 of the sixth active layer, forming the third node N3 of the pixel drive circuit. A first region 13-1 of the third active layer, a second region 14-2 of the fourth active layer, and a second region 15-2 of the fifth active layer may be connected to each other, and the first region 13-1 of the third active layer may simultaneously serve as the second region 14-2 of the fourth active layer and the second region 15-2 of the fifth active layer at the same time, forming a second node N2 of the pixel drive circuit. A second region 16-2 of the sixth active layer and a second region 17-2 of the seventh active layer may be connected to each other, and the second region 16-2 of the sixth active layer may serve as the second region 17-2 of the seventh active layer, forming a fourth node N4 of the pixel drive circuit. A first region 11-1 of the first active layer, a first region 12-1 of the second active layer, a first region 14-1 of the fourth active layer, a first region 15-1 of the fifth active layer and a first region 17-1 of the seventh active layer may be individually provided.

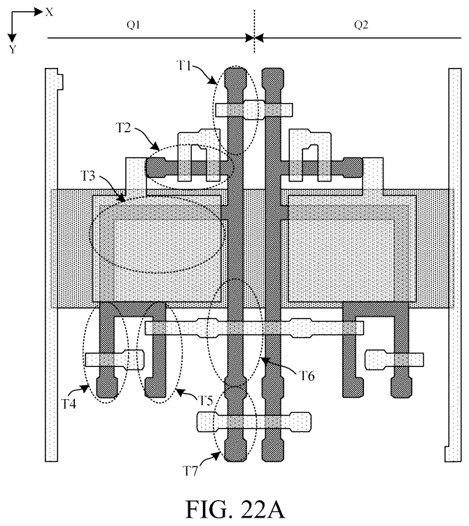

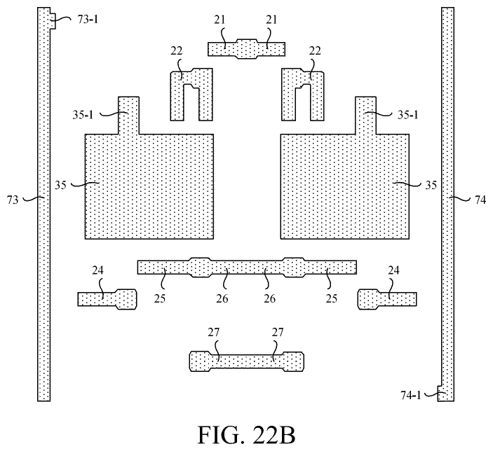

In an exemplary implementation, the semiconductor layers of adjacent circuit units in the first direction X may be substantially mirror symmetrical with respect to the unit reference line.
(23) Forming a pattern of a first conductive layer. In an exemplary implementation, forming the pattern of the first conductive layer may include: a second insulation thin film and a first conductive thin film are deposited sequentially on the substrate on which the aforementioned patterns are formed, and the first conductive thin film is patterned through a patterning process to form a second insulation layer that covers the pattern of the semiconductor layer, and a pattern of a first conductive layer arranged on the second insulation layer, as shown in FIGS. 22A and 22B, wherein FIG. 22B is a schematic diagram of the first conductive layer in FIG. 22A. In an exemplary implementation, the first conductive layer may be referred to as a first gate metal (GATE1) layer.

In an exemplary implementation, the pattern of the first conductive layer of each circuit unit in the display substrate at least includes: a first gate electrode 21, a second gate electrode 22, a fourth gate electrode 24, a fifth gate electrode 25, a sixth gate electrode 26, a seventh gate electrode 27 and a fifth electrode plate 35 of the storage capacitor.

In an exemplary implementation, a shape of the fifth electrode plate 35 of the storage capacitor may be a rectangle shape, corner portions of the rectangular shape may be provided with chamfered corners or grooves, an orthographic projection of the fifth electrode plate 35 on the substrate at least partially overlaps with an orthographic projection of the third active layer of the third transistor T3 on the substrate, and the fifth electrode plate 35 may serve as an electrode plate of the storage capacitor and a gate electrode of the third transistor T3 at the same time.

In an exemplary implementation, the fifth electrode plate 35 may be provided with a fifth electrode plate connection block 35-1. The fifth electrode plate connection block 35-1 may be in a block shape (e.g. rectangular) and may be arranged on a side of the fifth electrode plate 35 in the opposite direction of the second direction Y, a first terminal of the fifth electrode plate connection block 35-1 is connected to the fifth electrode plate 35, a second terminal of the fifth electrode plate connection block 35-1 extends in a direction away from the fifth electrode plate 35, and the fifth electrode plate connection block 35-1 is configured to be connected to the first region of the second active layer through a second connecting electrode formed subsequently.

In an exemplary implementation, the first gate electrode 21 may be in a shape of strip extending along the first direction X, and may be located on a side of the fifth electrode plate 35 in a direction opposite to the second direction Y, and a region where the first gate electrode 21 overlaps with the first active layer may serve as a gate electrode of the first transistor T1.

In an exemplary implementation, in the first direction X, first gate electrodes 21 in two partially adjacent circuit units may form an interconnected integral structure. For example, in an exemplary implementation, the first gate electrode 21 in the first circuit unit Q1 and the first gate electrode 21 in the second circuit unit Q2 adjacent in the first direction X may form an interconnected integral structure.

In an exemplary implementation, the second gate electrode 22 may be in a “U” shape, and may be located between the fifth electrode plate 35 and the first gate electrode 21, and a region where the second gate electrode 22 overlaps with the second active layer may serve as a gate electrode of the second transistor T2 of a double gate structure.

In an exemplary implementation, the fourth gate electrode 24 may be in a shape of strip extending along the first direction X, and may be located on a side of the fifth electrode plate 35 in the second direction Y, and a region where the fourth gate electrode 24 overlaps with the fourth active layer may serve as a gate electrode of the fourth transistor T4.

In an exemplary implementation, the fifth gate electrode 25 may be in a shape of strip extending along the first direction X, and may be located on a side of the fifth gate electrode 35 in the second direction Y, and a region where the fifth gate electrode 25 overlaps with the fifth active layer may serve as a gate electrode of the fifth transistor T5.

In an exemplary implementation, the sixth gate electrode 26 may be in a shape of strip extending along the first direction X, and may be located on a side of the fifth electrode plate 35 in the second direction Y, and a region where the sixth gate electrode 26 overlaps with the sixth active layer may serve as a gate electrode of the sixth transistor T6.

In an exemplary implementation, the sixth gate electrode 26 may be located on a side of the fifth gate electrode 25 in the first direction X or in an opposite direction of the first direction X, and connected to the fifth gate electrode 25.

In an exemplary implementation, in at least one circuit unit, the fifth gate electrode 25 and the sixth gate electrode 26 may form an interconnected integral structure.

In an exemplary implementation, in the first direction X, the sixth gate electrodes in two partially adjacent circuit units may be an interconnected integral structure. For example, the sixth gate electrode 26 in the first circuit unit Q1 and the sixth gate electrode 26 in the second circuit unit Q2 adjacent in the first direction X may form an interconnected integral structure.

In an exemplary implementation, in the first direction X, the fifth gate electrodes 25 and the sixth gate electrodes 26 in two partially adjacent circuit units may form an interconnected integral structure.

In the exemplary implementation, the seventh gate electrode 27 may be in a strip shape extending along the first direction X, and may be located on a side of the sixth gate electrode 26 away from the fifth electrode plate 35, and a region where the seventh gate electrode 27 overlaps with the seventh active layer may serve as a gate electrode of the seventh transistor T7. In an exemplary implementation, in the first direction X, the seventh gate electrodes in two partially adjacent circuit units may form an interconnected integral structure. For example, the seventh gate electrode 27 in the first circuit unit Q1 and the seventh gate electrode 27 in the second circuit unit Q2 adjacent in the first direction X may form an interconnected integral structure.

In an exemplary implementation, the aforementioned pattern of the first conductive layer of adjacent circuit units in the first direction X may be substantially mirror symmetrical with respect to the unit reference line.

In an exemplary implementation, the first conductive layer may include a first initial connection line 73 and a second initial connection line 74.

In an exemplary implementation, the first initial connection line 73 may be in a straight line shape or a bend line shape in which a main portion extends along the second direction Y, and may be located on a side of the first circuit unit Q1 in an opposite direction of the first direction X. A first initial connection block 73-1 may be arranged on the first initial connection line 73, the first initial connection block 73-1 may be in a block shape (e.g. rectangular) and connected to the first initial connection line 73, the first initial connection block 73-1 is configured to be connected to a first initial signal line formed subsequently.

In an exemplary implementation, in at least one circuit unit, the first initial connection line 73 and the first initial connection block 73-1 may form an interconnected integral structure.

In an exemplary implementation, the second initial connection line 74 may be in a straight line shape or a bend line shape in which a main portion extends along the second direction Y, and may be located on a side of the second circuit unit Q2 in the first direction X. A second initial connection block 74-1 may be arranged on the second initial connection line 74, the second initial connection block 74-1 may be in a block shape (e.g. rectangular) and connected to the second initial connection line 74, and the second initial connection block 74-1 is configured to be connected to a second initial signal line formed subsequently.

In an exemplary implementation, in at least one circuit unit, the second initial connection line 74 and the second initial connection block 74-1 may form an interconnected integral structure.

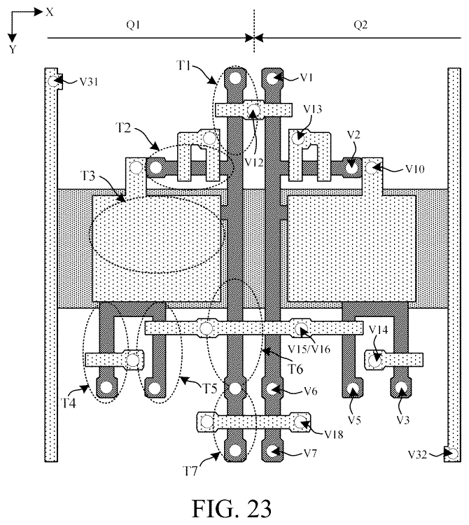

In an exemplary implementation, after the pattern of the first conductive layer is formed, a conductive processing may be performed on the semiconductor layer by using the first conductive layer as a shield, a semiconductor layer shielded by the first conductive layer forms channel regions of the first transistor T1 to the seventh transistor T7, and a semiconductor layer not shielded by the first conductive layer is made to be conductive, all of the first regions and the second regions of the first active layer to the seventh active layer are made to be conductive.
(24) A pattern of a third insulation layer is formed. In an exemplary implementation, forming a pattern of a third insulation layer may include: on the substrate on which the aforementioned patterns are formed, depositing a third insulation thin film, patterning the third insulation thin film through a patterning process to form a third insulation layer that covers the first conductive layer, wherein a plurality of vias are arranged in each circuit unit, as shown in FIG. 23.

In an exemplary implementation, the plurality of vias of each circuit unit in the display substrate at least include: a first vias V1, a second vias V2, a third vias V3, a fifth vias V5, a sixth vias V6, a seventh vias V7, a tenth vias V10, a twelfth vias V12, a thirteenth vias V13, a fourteenth vias V14, a fifteenth vias V15, a sixteenth vias V16, and an eighteenth vias V18.

In an exemplary implementation, an orthographic projection of the first via V1 on the substrate is within a range of an orthographic projection of the first region of the first active layer on the substrate, the third insulation layer and the second insulation layer within the first via V1 is etched away to expose a surface of the first region of the first active layer, and the first via V1 is configured to enable a subsequently formed first initial signal line to be connected to the first region of the first active layer through the via.

In an exemplary implementation mode, an orthographic projection of the second via V2 on the substrate is within a range of an orthographic projection of the first region of the second active layer on the substrate, the third insulation layer and the second insulation layer within the second via V2 is etched away to expose a surface of the first region of the second active layer, and the second via V2 is configured to enable a subsequently formed second connection electrode to be connected to the first region of the second active layer through the via.

In an exemplary implementation, an orthographic projection of the third via V3 on the substrate is within a range of an orthographic projection of the first region of the fourth active layer on the substrate, the third insulation layer and the second insulation layer within the third via V3 is etched away to expose a surface of the first region of the fourth active layer, and the third via V3 is configured to enable a subsequently formed third connection electrode to be connected to the first region of the fourth active layer through the via.

In an exemplary implementation, an orthographic projection of the fifth via V5 on the substrate is within a range of an orthographic projection of the first region of the fifth active layer on the substrate, the third insulation layer and the second insulation layer within the fifth via V5 is etched away to expose a surface of the first region of the fifth active layer, and the fifth via V5 is configured to enable a subsequently formed fourth connection electrode to be connected to the first region of the fifth active layer through the via.

In an exemplary implementation, an orthographic projection of the sixth via V6 on the substrate is within a range of an orthographic projection of the second region of the sixth active layer (also the second region of the seventh active layer) on the substrate, the third insulation layer and the second insulation layer within the sixth via V6 are etched away to expose a surface of the second region of the sixth active layer (also the second region of the seventh active layer), and the sixth via V6 is configured to enable a subsequently formed fifth connection electrode to be connected to the second region of the sixth active layer (also the second region of the seventh active layer) through the via.

In an exemplary implementation mode, an orthographic projection of the seventh via V7 on the substrate is within a range of an orthographic projection of the first region of the seventh active layer on the substrate, the third insulation layer and the second insulation layer within the seventh via V7 is etched off to expose a surface of the first region of the seventh active layer, and the seventh via V7 is configured to enable a subsequently formed second initial signal line to be connected to the first region of the seventh active layer through the via.

In an exemplary implementation, an orthographic projection of the tenth via V10 on the substrate is located within a range of an orthographic projection of the fifth electrode plate connection block 35-1 of the fifth electrode plate 35 on the substrate, the third insulation layer within the tenth via V10 is etched away to expose a surface of the fifth electrode plate connection block 35-1, and the tenth via V10 is configured to enable a subsequently formed second connection electrode to be connected to the fifth electrode plate connection block 35-1 through the via.

In an exemplary implementation, an orthogonal projection of the twelfth via V12 on the substrate is within a range of an orthogonal projection of the first gate electrode 21 on the substrate, the third insulation layer within the twelfth via V12 is etched off to expose a surface of the first gate electrode 21, the twelfth via V12 is configured to enable a subsequently formed fourth scan signal line to be connected to the first gate electrode 21 through the via, and the twelfth via V12 may serve as the first gate via of the present disclosure.

In the exemplary implementation, because the first gate electrodes 21 in adjacent circuit units in the first direction X form an interconnected integral structure, the twelfth via V12 may be arranged between the adjacent circuit units, and the adjacent circuit units may share a same twelfth via V12.

In an exemplary implementation, an orthographic projection of the thirteenth via V13 on the substrate is within a range of an orthographic projection of the second gate electrode 22 on the substrate, the third insulation layer within the thirteenth via V13 is etched away to expose a surface of the second gate electrode 22, and the thirteenth via V13 is configured to enable a subsequently formed second scan signal line to be connected to the second gate electrode 22 through the via.

In an exemplary implementation, an orthographic projection of the fourteenth via V14 on the substrate is within the range of an orthographic projection of the fourth gate electrode 24 on the substrate, the third insulation layer in the fourteenth via V14 is etched away to expose a surface of the fourth gate electrode 24, and the fourteenth via V14 is configured to enable a subsequently formed third scan signal line to be connected to the fourth gate electrode 24 through the via.

In an exemplary implementation, an orthographic projection of the fifteenth via V15 on the substrate is within a range of an orthographic projection of the fifth gate electrode 25 on the substrate, the third insulation layer in the fifteenth via V15 is etched away to expose a surface of the fifth gate electrode 25, and the fifteenth via V15 is configured to enable a subsequently formed light emitting signal line to be connected to the fifth gate electrode 25 through the via.

In an exemplary implementation, an orthographic projection of the sixteenth via V16 on the substrate is within a range of an orthographic projection of the sixth gate electrode 26 on the substrate, the third insulation layer within the sixteenth via V16 is etched away to expose a surface of the sixth gate electrode 26, and the sixteenth via V16 is configured to enable a subsequently formed light emitting signal line to be connected to the sixth gate electrode 26 through the via.

In an exemplary implementation, because the fifth gate electrode 25 and the sixth gate electrode 26 in one circuit unit are of an interconnected integral structure, the fifteenth via V15 and the sixteenth via V16 may be a same via.

In an exemplary implementation, an orthographic projection of the eighteenth via V18 on the substrate is within a range of an orthographic projection of the seventh gate electrode 27 on the substrate, the third insulation layer in the eighteenth via V18 is etched away to expose a surface of the seventh gate electrode 27, and the eighteenth via V18 is configured to enable a subsequently formed first scan signal line to be connected to the seventh gate electrode 27 through the via.

In an exemplary implementation, a plurality of vias of adjacent circuit units in the first direction X may be substantially mirror symmetrical with respect to the unit reference line.

In an exemplary implementation, the third insulation layer may include a first initial via V31 and a second initial via V32.

In an exemplary implementation, an orthogonal projection of the first initial via V31 on the substrate is within a range of an orthogonal projection of the first initial connection block 73-1 of the first initial connection line 73 on the substrate, the third insulation layer within the first initial via V31 is etched off to expose a surface of the first initial connection block 73-1, and the first initial via V31 is configured to enable a subsequent formed first initial signal line to be connected to the first initial connection block 73-1 through the via.

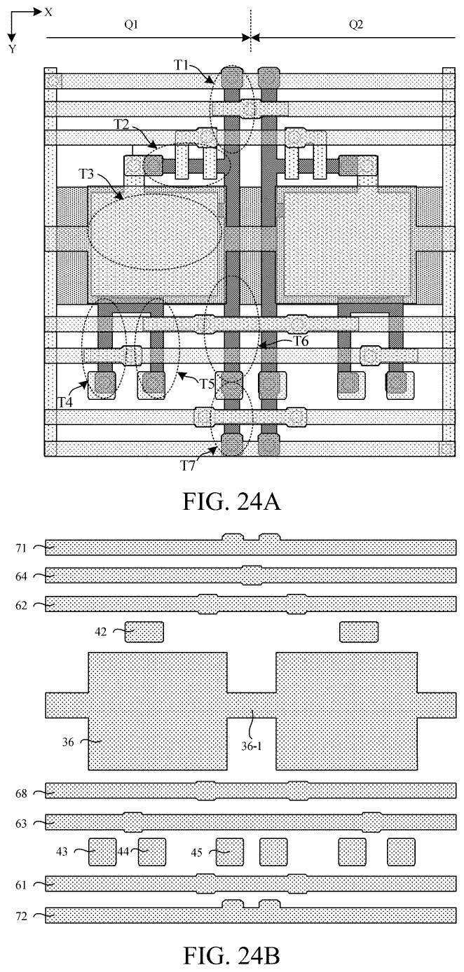

In an exemplary implementation, an orthogonal projection of the second initial via V32 on the substrate is within a range of an orthogonal projection of the second initial connection block 74-1 of the second initial connection line 74 on the substrate, the third insulation layer within the second initial via V32 is etched off to expose a surface of the second initial connection block 74-1, and the second initial via V32 is configured to enable a subsequent formed second initial signal line to be connected to the second initial connection block 74-1 through the via.
(25) A pattern of a third conductive layer is formed. In an exemplary implementation mode, forming a pattern of the third conductive layer may include: depositing a third conductive thin film on the substrate on which the aforementioned patterns are formed, and patterning the third conductive thin film using a patterning process to form the third conductive layer disposed on the third insulation layer, as shown in FIG. 24A and FIG. 24B. FIG. 24B is a schematic diagram of the third conductive layer in FIG. 24A. In an exemplary implementation, the third conductive layer may be referred to as a first source-drain metal (SD1) layer.

In an exemplary implementation, the pattern of the third conductive layer of each circuit unit in the display substrate may include: a sixth electrode plate 36 of a storage capacitor, a second connection electrode 42, a third connection electrode 43, a fourth connection electrode 44, a fifth connection electrode 45, a first scan signal line 61, a second scan signal line 62, a third scan signal line 63, a fourth scan signal line 64, a light emitting signal line 68, a first initial signal line 71, and a second initial signal line 72.

In an exemplary implementations, the sixth electrode plate 36 of the storage capacitor may be in a rectangle shape, corner portions of the rectangular shape may be provided with chamfered corners, an orthographic projection of the sixth electrode plate 36 on the substrate at least overlaps with an orthographic projection of the fifth electrode plate 35 on the substrate, the sixth electrode plate 36 may serve as the other electrode plate of the storage capacitor, and the fifth electrode plate 35 and the sixth electrode plate 36 form the storage capacitor of the pixel drive circuit.

In an exemplary implementation, the sixth electrode plate 36 may be provided with a sixth plate connection block 36-1. The sixth plate connecting block 36-1 may be a strip shape extending along the first direction X, and may be provided on a side of the sixth electrode plate 36 in the first direction X or in an opposite direction of the first direction X. A first terminal of the sixth plate connecting block 36-1 is connected to the sixth electrode plate 36, and a second terminal of the sixth plate connecting block 36-1 extends to an adjacent circuit unit and is connected to the sixth electrode plate 36 of the adjacent circuit unit.

In an exemplary implementation, the sixth electrode plate 36 and the sixth plate connection block 36-1 in one circuit unit may form an interconnected integral structure.

In an exemplary implementation, a plurality of sixth electrode plates 36 and a plurality of sixth plate connecting blocks 36-1 arranged at intervals in one unit row may form an interconnected integral structure. Because the sixth electrode plates 36 are connected to a first power supply line formed subsequently, the plurality of sixth electrode plates 36 in an integral structure of a plurality of circuit units may be reused as a transverse power supply line extending along the first direction X, which not only ensures that the plurality of sixth electrode plates 36 in a unit row are at a same potential, but also reduces a voltage drop of a first power supply signal, which is beneficial to improving uniformity of the panel, avoiding display defect of the display substrate, and ensuring the display effect of the display substrate.

In the exemplary implementation, the first scan signal line 61 may be in a straight line shape or a bend line shape in which a main portion extends along the first direction X, and may be located on a side of the sixth electrode plate 36 in the second direction Y. The first scan signal line 61 is connected to the seventh gate electrode 27 through the eighteenth via V18, thereby achieving that the first scan signal line 61 is connected to the gate electrode of the seventh transistor T7, and the first scan signal line 61 controls conduction and disconnection of the seventh transistor T7.

In the exemplary implementation, the second scan signal line 62 may be in a straight line shape or a bend line shape in which a main portion extends along the first direction X, and may be located on a side of the sixth electrode plate 36 in an opposite direction of the second direction Y. The second scan signal line 62 is connected to the second gate electrode 22 through the thirteenth via V13, thereby achieving that the second scan signal line 62 is connected to the gate electrode of the second transistor T2, and the second scan signal line 62 can control conduction and disconnection of the second transistor T2.

In the exemplary implementation, the third scan signal line 63 may be in a straight line shape or a bend line shape in which a main portion extends along the first direction X, and may be located between the sixth electrode plate 36 and the first scan signal line 61, and the third scan signal line 63 is connected to the fourth gate electrode 24 through the fourteenth via V14, thereby achieving that the third scan signal line 63 is connected to the gate electrode of the fourth transistor T4, and the third scan signal line 63 can control conduction and disconnection of the fourth transistor T4.

In an exemplary implementation, the fourth scan signal line 64 may be in a straight line shape or bend line shape in which a main portion extends along the first direction X, and may be located on a side of the second scan signal line 62 away from the sixth electrode plate 36. The fourth scan signal line 64 is connected to the first gate electrode 21 through the twelfth via V12, thereby achieving that the fourth scan signal line 64 is connected to the gate electrode of the first transistor T1, and the fourth scan signal line 64 can control conduction and disconnection of the first transistor T1.

In the exemplary implementation, a shape of the light emitting signal line 68 may be a straight line or a bend line in which a main portion extends along the first direction X. The light emitting signal line 68 may be located between the sixth electrode plate 36 and the third scan signal line 63. The light emitting signal line 68 is connected to the fifth gate electrode 25 (also the sixth gate electrode 26) through the fifteenth via V15 (also the sixteenth via V16), thereby achieving that the light emitting signal line 68 is connected to the gate electrode of the fifth transistor T5 and the gate electrode of the sixth transistor T6. The light emitting signal line 68 can simultaneously control conduction and disconnection of the fifth transistor T5 and the sixth transistor T6.

In the exemplary implementation, a shape of the first initial signal line 71 may be a straight line or a bend line in which a main portion extends along the first direction X, the first initial signal line 71 may be located on a side of the fourth scan signal line 64 away from the sixth electrode plate 36. The first initial signal line 71 is connected to the first region of the first active layer through the first via V1, thereby achieving that the first initial signal line 71 is connected to the first electrode of the first transistor T1, and the first initial signal line 71 can write a first initial signal to the first electrode of the first transistor T1.

In an exemplary implementation, the first initial signal line 71 is connected to the first initial connection block 73-1 through the first initial via V31. Because the first initial connection block 73-1 is connected to the first initial connection line 73, an interconnection of the first initial signal line 71 in which a main portion extending along the first direction X and the first initial connection line 73 in which a main portion extending along the second direction Y is thus achieved, so that the first initial signal line 71 and the first initial connection line 73 form a mesh-shaped network communication structure for transmitting a first initial signal on the display substrate, which not only can effectively reduce a resistance of the first initial signal line and reduce a voltage drop of the first initial signal, but also can effectively improve uniformity of the first initial signal in the display substrate, effectively improve uniformity of display, and improve display attribute and display quality.

In the exemplary implementation, the second initial signal line 72 may be in a straight line shape or a bend line shape in which a main portion extends along the first direction X, the second initial signal line 72 may be located on a side of the first scan signal line 61 away from the sixth electrode plate 36, and the second initial signal line 72 is connected to the first region of the seventh active layer through the seventh via V7, thereby achieving that the second initial signal line 72 is connected to the first electrode of the seventh transistor T7, and the second initial signal line 72 may write a second initial signal to the first electrode of the seventh transistor T7.

In an exemplary implementation, the second initial signal line 72 is connected to the second initial connection block 74-1 through the second initial via V32. Because the second initial connection block 74-1 is connected to the second initial connection line 74, an interconnection of the second initial signal line 72 in which a main portion extending along the first direction X and the second initial connection line 74 with a main portion extending along the second direction Y is thus achieved, so that the second initial signal line 72 and the second initial connection line 74 form a mesh-shaped network communication structure for transmitting a second initial signal on the display substrate, which not only can effectively reduce a resistance of the second initial signal line and reduce a voltage drop of the second initial signal, but also can effectively improve uniformity of the second initial signal in the display substrate, effectively improve uniformity of display, and improve display attribute and display quality.

In an exemplary implementation, only one of the first initial connection line 73 and the second initial connection line 74 may be arranged in one unit column, and the first initial connection line 73 and the second initial connection line 74 are alternately arranged in the first direction X. For example, the first initial connection line 73 may be arranged in a unit column in which a first circuit unit and a third circuit unit are located, and the second initial connection line 74 may be arranged in a unit column in which a second circuit unit and a fourth circuit unit are located.

In exemplary implementations, the first initial connection lines 73 of adjacent unit columns may form an interconnected integral structure, or the adjacent unit columns may share a same first initial connection line 73. For example, a unit column in which the first circuit unit Q1 is located and an adjacent unit column in an opposite direction of the first direction X may share a same first initial connection line 73.

In an exemplary implementation, the second initial connection lines 74 of adjacent unit columns may form an interconnected integral structure, or the adjacent unit columns may share a same second initial connection line 74. For example, a unit column in which the second circuit unit Q2 is located and an adjacent unit column in first direction X may share a same second initial connection line 74.

In an exemplary implementation, the first scan signal line 61, the third scan signal line 63, the light emitting signal line 68, and the second initial signal line 72 may be located on a side of the sixth electrode plate 36 in the second direction Y. Herein, the light emitting signal line 68 may be located on a side of the sixth electrode plate 36 in the second direction Y, the third scan signal line 63 may be located on a side of the light emitting signal line 68 away from the sixth electrode plate 36, the first scan signal line 61 may be located on a side of the third scan signal line 63 away from the sixth electrode plate 36, and the second initial signal line 72 may be located on a side of the first scan signal line 61 away from the sixth electrode plate 36.

In an exemplary implementation, the second scan signal line 62, the fourth scan signal line 64, and the first initial signal line 71 may be located on a side of the sixth electrode plate 36 in an opposite direction of the second direction Y. Herein, the second scan signal line 62 may be located on a side of the sixth electrode plate 36 in an opposite direction of the second direction Y, the fourth scan signal line 64 may be located on a side of the second scan signal line 62 away from the sixth electrode plate 36, and the first initial signal line 71 may be located on a side of the fourth scan signal line 64 away from the sixth electrode plate 36.

In an exemplary implementation, the second connection electrode 42 may be in a block shape (e.g. rectangular) and may be arranged between the sixth electrode plate 36 and the second scan signal line 62, a first terminal of the second connection electrode 42 is connected to the first region of the second active layer through the second via V2, and a second terminal of the second connection electrode 42 is connected to the fifth electrode plate connection block 35-1 through the tenth via V10. Because the fifth electrode plate connection block 35-1 is connected to the fifth electrode plate 35, and the fifth electrode plate 35 is the gate electrode of the third transistor T3, thus the second connection electrode 42 enables that the first electrode of the second transistor T2, the gate electrode of the third transistor T3, and the fifth electrode plate 35 of the storage capacitor have the same potential, such that the first node N1 of the pixel drive circuit is formed.

In an exemplary implementation, the third connection electrode 43 may be in a block shape (e.g. rectangular), and may be arranged between the first scan signal line 61 and the third scan signal line 63, and the third connection electrode 43 is connected to the first region of the fourth active layer through the third via V3. In an exemplary implementation mode, the third connection electrode 43 is configured to be connected to a data signal line formed subsequently.

In an exemplary implementation, the fourth connection electrode 44 may be in a block shape (e.g. rectangular), and may be arranged between the first scan signal line 61 and the third scan signal line 63, and the fourth connection electrode 44 is connected to the first region of the fifth active layer through the fifth via V5. In an exemplary implementation, the fourth connection electrode 44 is configured to be connected to a first power supply line formed subsequently.

In an exemplary implementation, the fifth connection electrode 45 may be in a block shape (e.g. rectangular) and may be arranged between the first scan signal line 61 and the third scan signal line 63, and the fifth connection electrode 45 is connected to the second region of the sixth active layer (also the second region of the seventh active layer) through the sixth via V6. In an exemplary implementation, the seventh connection electrode 45 is configured to be connected to an anode connection electrode to be formed subsequently.

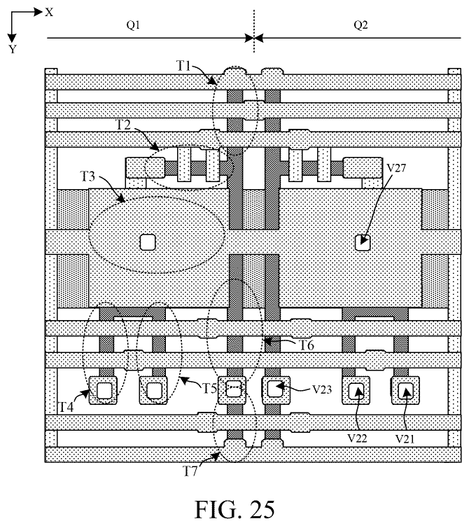

In an exemplary implementation, the third conductive layers of adjacent circuit units in the first direction X may be substantially mirror symmetrical with respect to the unit reference line. (26) Forming a pattern of a fourth insulation layer. In an exemplary implementation, forming a pattern of a fourth insulation layer may include: depositing a fourth insulation thin film on the substrate on which the aforementioned patterns are formed, patterning the fourth insulation thin film through a patterning process, forming a fourth insulation layer that covers the third conductive layer, wherein a plurality of vias are arranged in each circuit unit, as shown in FIG. 25.

In an exemplary implementation mode, the plurality of vias in each circuit unit in the display substrate at least include: a twenty-first via V21, a twenty-second via V22, a twenty-third via V23, and a twenty-fourth via V27.

In an exemplary implementation, an orthographic projection of the twenty-first via V21 on the substrate is located within a range of an orthographic projection of the third connection electrode 43 on the substrate, the fourth insulation layer within the twenty-first via V21 is removed to expose a surface of the third connection electrode 43, and the twenty-first via V21 is configured to enable a subsequently formed data signal line to be connected to the third connection electrode 43 through the via.

In an exemplary implementation, an orthographic projection of the twenty-second via V22 on the substrate is located within a range of an orthographic projection of the fourth connection electrode 44 on the substrate, the fourth insulation layer within the twenty-second via V22 is removed to expose a surface of the fourth connection electrode 44, and the twenty-second via V22 is configured to enable a subsequently formed first power supply line to be connected to the fourth connection electrode 44 through the via.

In an exemplary implementation, an orthographic projection of the twenty-third via V23 on the substrate is located within a range of an orthographic projection of the fifth connection electrode 45 on the substrate, the fourth insulation layer within the twenty-third via V23 is removed to expose a surface of the fifth connection electrode 45, and the twenty-third via V23 is configured to enable a subsequently formed anode connection electrode to be connected to the fifth connection electrode 45 through the via.

In an exemplary implementation, an orthographic projection of the twenty-seventh via V27 on the substrate is within a range of an orthographic projection of the sixth electrode plate 36 on the substrate, the fourth insulation layer in the twenty-seventh via V27 is removed to expose a surface of the sixth electrode plate 36, and the twenty-seventh via V27 is configured to enable a subsequently formed first power supply line to be connected to the sixth electrode plate 36 through the twenty-seventh via V27.

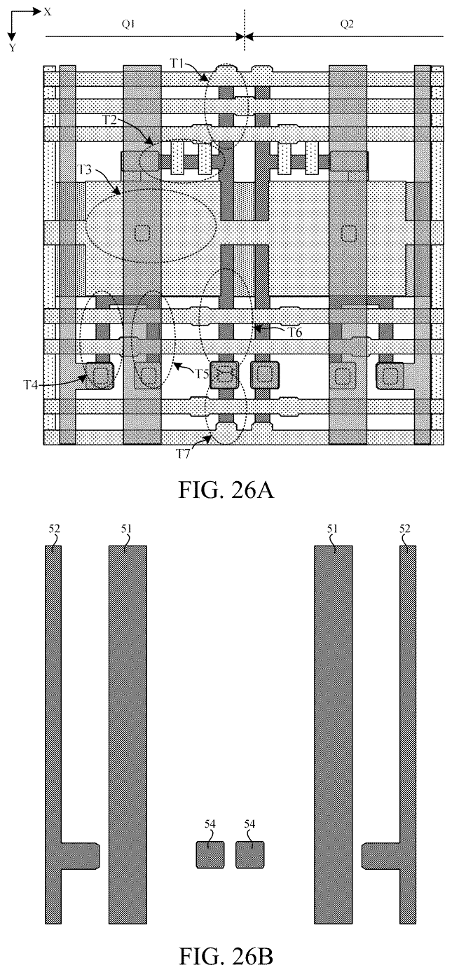

In an exemplary implementation, a plurality of vias of adjacent circuit units in the first direction X may be substantially mirror symmetrical with respect to the unit reference line.
(27) A pattern of a fourth conductive layer is formed. In an exemplary implementation, forming a pattern of a fourth conductive layer pattern may include: depositing a fourth conductive film on a substrate on which the aforementioned patterns are formed, patterning the fourth conductive film using a patterning process to form a fourth conductive layer arranged on the fourth insulation layer, as shown in FIGS. 26A and 26B. FIG. 26B is a schematic diagram of the fourth conductive layer in FIG. 26A. In an exemplary implementation, the fourth conductive layer may be referred to as a second source-drain metal (SD2) layer.

In an exemplary implementation, each of patterns of fourth conductive layers of a plurality of circuit units in the display substrate may include: a first power supply line 51, a data signal line 52 and an anode connection electrode 54.

In an exemplary implementation, the first power supply line 51 may be in a straight line shape or a bend line shape in which a main portion extending along the second direction Y. On one hand, the first power supply line 51 is connected to the fourth connection electrode 44 through the twenty-second via V22, and on the other hand, the first power supply line 51 is connected to the sixth electrode plate 36 through the twenty-seventh via V27. Because the fourth connection electrode 44 is connected to the first region of the fifth active layer through the via, thus the connection of the first power supply line 51 with the first electrode of the fifth transistor T5 and the sixth electrode plate 36 of the storage capacitor is achieved. The first power supply line 51 can write the first power supply signal to the first electrode of the fifth transistor T5 and the sixth electrode plate 36 of the storage capacitor.

In an exemplary implementation, an orthographic projection of the first power supply line 51 on the substrate is overlapped, at least partially, with an orthographic projection of the second connection electrode 42 on the substrate. Because the second connection electrode 42 serves as the first node N1 in the pixel drive circuit, thus the first power supply line 51 which is at a constant voltage can effectively shield an influence of other signals in the pixel drive circuit on the first node N1, thereby avoiding an influence of other signals (such as the data voltage jump) on a potential at the first node N1 in the pixel drive circuit, and improving the display effect.

In the exemplary implementation, the data signal line 52 may be in a shape of a straight line or a bend line in which a main portion extends along the second direction Y, and the data signal line 52 is connected to the third connection electrode 43 through the twenty-first via V21. Because the third connection electrode 43 is connected to the first region of the fourth active layer through a via, the data signal of the data signal line 52 is written to the first electrode of the fourth transistor T4 is achieved.

In an exemplary implementation, the anode connection electrode 54 may be in a block shape (e.g. rectangular), and the anode connection electrode 54 is connected to the fifth connection electrode 45 through the twenty-third via V23. Because the fifth connection electrode 45 is connected to the second region of the sixth active layer (also the second region of the seventh active layer) through a via, it is achieved that the anode connection electrode 54 is connected to the second electrode of the sixth transistor T6 and the second electrode of the seventh transistor T7. In an exemplary implementation, the anode connection electrode 54 is configured to connect with the anode formed later, thereby the pixel drive circuit can drive a light emitting device.

In an exemplary implementation, the first power supply line 51 and the data signal line 52 may be designed with equal width or may be designed with non-equal width, which not only facilitates the layout of the pixel structure, but also reduces the parasitic capacitance between the signal lines.

In the exemplary implementation, because the fifth electrode plate 35 of the storage capacitor has the potential of the first node N1 and the sixth electrode plate 36 of the storage capacitor has the potential of the first power supply line 51, thus the fifth electrode plate 35 and the sixth electrode plate 36 form the storage capacitor. In an exemplary implementation, the size of the storage capacitor may be increased by reducing the thickness of the insulation layer between the first conductive layer and the third conductive layer, changing the dielectric constant of the insulation layer, and the like.

In an exemplary implementation, the fourth conductive layers of adjacent circuit units in the first direction X may be substantially mirror symmetrical with respect to the unit reference line.

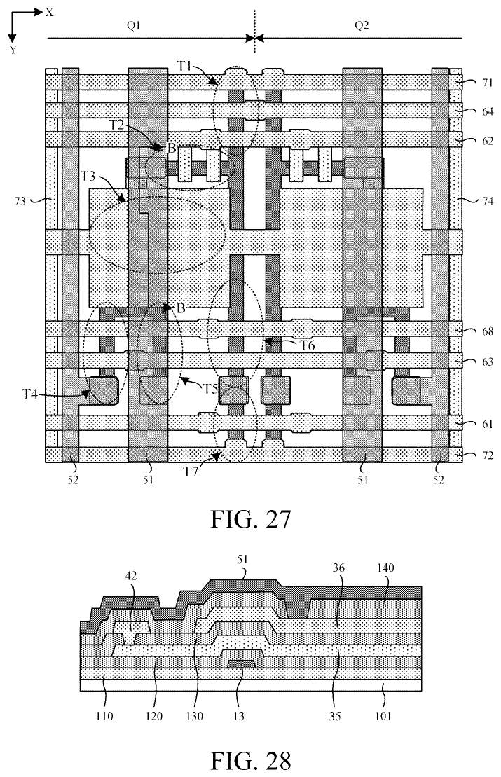

FIG. 27 is a schematic diagram of a planar structure of yet another display substrate according to an exemplary embodiment of the present disclosure, and FIG. 28 is a sectional view taken along a B-B direction in FIG. 27. A main structure of the display substrate according to the present embodiment is substantially the same as that of the display substrate shown in FIG. 18 and FIG. 19, except that the display substrate according to the present embodiment is not provided with a barrier shield metal layer.

As shown in FIGS. 27 and 28, in an exemplary implementation, on a plane perpendicular to the display substrate, the display substrate may include: a first insulation layer 110 arranged on the substrate 101, a semiconductor layer arranged on a side of the first insulation layer 110 away from the substrate 101, a second insulation layer 120 arranged on a side of the semiconductor layer away from the substrate 101, a first conductive layer (GATE 1) arranged on a side of the second insulation layer 120 away from the substrate 101, a third insulation layer 130 arranged on a side of the first conductive layer away from the substrate 101, a third conductive layer (SD1) arranged on a side of the third insulation layer 130 away from the substrate 101, a fourth insulation layer 140 arranged on a side of the third conductive layer away from the substrate 101, and a fourth conductive layer (SD2) arranged on a side of the fourth insulation layer 140 away from the substrate 101.

In an exemplary implementation, the semiconductor layer may at least include a third active layer 13, and the first conductive layer may at least include a fifth electrode plate 35. The third conductive layer may at least include a sixth electrode plate 36 and a second connection electrode 42, an orthographic projection of the sixth electrode plate 36 on the substrate at least partially overlaps with an orthographic projection of the fifth electrode plate 35 on the substrate, and a second connection electrode 42 is connected to the fifth electrode plate 35 through a via. The fourth conductive layer may at least include a first power supply line 51, the first power supply line 51 is connected to the sixth electrode plate 36 through a via.

In an exemplary implementation, the first conductive layer may further include a first initial connection line 73, a second initial connection line 74, and gate electrodes of a plurality of transistors. The third conductive layer may further include a first scan signal line 61, a second scan signal line 62, a third scan signal line 63, a fourth scan signal line 64, a light emitting signal line 68, a first initial signal line 71, a second initial signal line 72, and a plurality of connection electrodes. The fourth conductive layer may further include a data signal line 52.

In the exemplary implementation, the present embodiment shows a preparation process of the display substrate substantially the same as that of the aforementioned embodiments, except that there is no operation of forming a shield metal layer.

A display substrate adopts a structure of double GATE double SD, and includes: a semiconductor layer, a first GATE metal layer, a second GATE metal layer, a first source drain metal layer, and a second source drain metal layer sequentially arranged on the substrate. Generally, 12 to 14 times of patterning (Mask) process are required. Not only the process time is long, the production cost is high, but also the intermediate film layer is complex, and the finished product yield is low.

The exemplary embodiment of the present disclosure provides a display substrate, which adopts a structure of single GATE double SD and includes a semiconductor layer, a first GATE metal layer, a first source drain metal layer and a second source drain metal layer sequentially arranged on the substrate. By reducing the second GATE metal layer, the times of patterning process are effectively reduced, the process time is shortened, the production capacity is improved, the production cost is reduced, and the intermediate film layer is simplified, the layout space is optimized, and the finished product yield is effectively improved.

In the display substrate of the present disclosure, a first gate metal layer and a first source drain metal layer are used to form electrode plates of a storage capacitor. Compared with the existing structure in which the first gate metal layer and the second gate metal layer are used to form the electrode plates of a capacitor, the present disclosure not only reduces the patterning process of the second gate metal layer, but also reduces the number of connecting vias and connecting electrodes, reduces the process complexity, improves the process quality, reduces the occupied area of the connecting vias and connecting electrodes, and is conducive to improving the resolution.

In the display substrate of the present disclosure, a first source drain metal layer is used to form a scan signal line and a light emitting signal line. Compared with the existing structure in which the second gate metal layer (usually metal Mo) is used to form the signal line, because the first source drain metal layer is relatively thick, and the metal Al with low resistance is usually used, thus a resistance of the signal line is effectively reduced (resistance is reduced by about 80%), and a resistance-capacitance load (RC loading) of the signal line can be reduced by an order of magnitude, which not only increases the charging time and is conducive to high-frequency pixel drive, but also is conducive to reducing Cross Talk between pixels.

In the display substrate of the present disclosure, a structure in which the semiconductor layer and the wiring layer are separated is used, which can reduce the crosstalk of the signal line to the active layer in the transistor and reduce the parasitic capacitance. Due to the large distance between the first source drain metal layer and other metal film layers, the optimization of the parasitic capacitance of the signal line and the node has been significantly improved. The parasitic capacitance of the signal line can be reduced by about 50% on average, and the RC delay can be reduced by an order of magnitude. The parasitic capacitance between the data signal and the first node N1 is an important parameter for generating crosstalk. The display substrate of the present disclosure can effectively reduce the parasitic capacitance, optimize the performance index of the crosstalk, and make it beneficial to high frequency and reduce the crosstalk of pixels.

The present disclosure adopts a display substrate with a 7T1C pixel drive circuit structure, adopts a modular design, and a plurality of switching transistors are controlled by independent scan signal lines, which can be conveniently matched with a gate drive circuit and can freely adjust the timing, and is conducive to expanding into a compatible LTPO pixel circuit design. For example, the second transistor T2 may be replaced with an oxide transistor.

The present disclosure adopts a display substrate with a 9T2C pixel drive circuit structure. By arranging a first reference signal line in which a main portion extends along the first direction X and a first reference connection line in which a main portion extends along the second direction Y, and interconnecting the first reference signal line with the first reference connection line, a mesh-shaped network communication structure for transmitting a first reference signal is formed on the display substrate, which not only effectively reduces a resistance of the first reference signal line and reduces a voltage drop of the first reference signal, but also effectively improves a uniformity of the first reference signal in the display substrate, effectively improves a uniformity of the display, and improves display attribute and display quality.

The present disclosure adopts a display substrate with a structure of 7T1C pixel drive circuit. By arranging a first initial signal line in which a main portion extends along the first direction X and a first initial connection line 73 in which a main portion extends along the second direction Y, and interconnecting the first initial signal line with the first initial connection line, a mesh-shaped network communication structure for transmitting a first initial signal is formed on the display substrate, which not only can effectively reduce a resistance of the first initial signal line and reduce a voltage drop of the first initial signal, but also can effectively improve uniformity of the first initial signal in the display substrate, effectively improve uniformity of display, and improve display attribute and display quality.

The present disclosure adopts a display substrate with a structure of 7T1C pixel drive circuit. By arranging a second initial signal line in which a main portion extends along the first direction X and a second initial connection line 73 in which a main portion extends along the second direction Y, and interconnecting the second initial signal line with the second initial connection line, a mesh-shaped network communication structure for transmitting a second initial signal is formed on the display substrate, which not only can effectively reduce a resistance of the second initial signal line and reduce a voltage drop of the second initial signal, but also can effectively improve uniformity of the second initial signal in the display substrate, effectively improve uniformity of display, and improve display attribute and display quality.

By providing the first power supply line to cover the first node N1 of the pixel drive circuit, the embodiment of the present disclosure effectively avoids another signal from affecting potential of the first node N1 of the pixel drive circuit, and improves a display effect.

The preparation process in the present disclosure may be compatible well with an existing preparation process, is simple in process implementation, is easy to implement, and has a high production efficiency, a low production cost, and a high yield.

The structure shown and mentioned above in the present disclosure and the preparation process therefor are merely an exemplary description. In an exemplary implementation, the corresponding structures may be altered and the patterning processes may be added or reduced according to actual needs. For example, the LTPO display substrate may be formed by replacing the polysilicon transistors in the display substrate with oxide transistors, or by replacing part of the polysilicon transistors in the display substrate with oxide transistors, which is not limited herein in the present disclosure.

In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The present disclosure further provides a method for manufacturing a display substrate, for manufacturing the display substrate according to the foregoing embodiments. In an exemplary implementation, the display substrate includes a plurality of circuit units forming a plurality of unit rows and a plurality of unit columns, at least one circuit unit includes a pixel drive circuit and a plurality of scan signal lines connected to the pixel drive circuit, and the pixel drive circuit includes at least a plurality of transistors. The preparation method may include:
forming a first gate metal layer on the substrate, wherein a gate electrode of at least one transistor is arranged in the first gate metal layer;
forming a first source drain metal layer on the first gate metal layer, wherein at least one scan signal line is arranged on the first source drain metal layer, and the scan signal line is connected to the gate electrode through a via.

The present disclosure further provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are described as above, the described contents are only implementations which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. A display substrate, comprising: a plurality of circuit units forming a plurality of unit rows and a plurality of unit columns, wherein at least one circuit unit comprises a pixel drive circuit and a plurality of scan signal lines connected to the pixel drive circuit, the pixel drive circuit at least comprises a plurality of transistors; in a direction perpendicular to the display substrate, the display substrate at least comprises a first gate metal layer arranged on a substrate and a first source drain metal layer arranged on a side of the first gate metal layer away from the substrate, a gate electrode of at least one transistor is arranged in the first gate metal layer, and at least one scan signal line is arranged in the first source drain metal layer, and the scan signal line is connected to the gate electrode through a via.

2. The display substrate of claim 1, wherein the plurality of transistors at least comprise a first transistor as a first initialization transistor, the first transistor at least comprises a first gate electrode, the first gate electrode is connected to a fourth scan signal line, and a first electrode of the first transistor is connected to a first initial signal line; the first gate electrode is arranged in the first gate metal layer, the fourth scan signal line is arranged in the first source drain metal layer, and the fourth scan signal line is connected to the first gate electrode through a first gate via.

3. The display substrate of claim 2, wherein in a unit row direction, first gate electrodes in at least one adjacent two circuit units are of an interconnected integral structure.

4. The display substrate of claim 2, wherein in a unit row direction, at least one adjacent two circuit units share a same first gate via.

5. The display substrate of claim 2, wherein a shape of the first initial signal line is a straight line or a bend line extending along the unit row direction; the at least one circuit unit further comprises a first initial connection line, the first initial connection line has a straight line shape or a bend line shape extending along a unit column direction, and the first initial connection line is connected to the first initial signal line to form a network communication structure for transmitting a first initial signal.

6. The display substrate of claim 5, wherein the first initial connection line is arranged in the first gate metal layer, and the first initial signal line is arranged in the first source drain metal layer.

7. The display substrate of claim 2, wherein the display substrate further comprises a second source drain metal layer arranged on a side of the first source drain metal layer away from the substrate, the first initial signal line is in a straight line shape or a bend line shape extending along the unit column direction, and the first initial signal line is arranged in the second source drain metal layer.

8. The display substrate of claim 1, wherein the plurality of transistors at least comprise a seventh transistor as a second initialization transistor, the seventh transistor at least comprises a seventh gate electrode, the seventh gate electrode is connected to a first scan signal line, and a first electrode of the seventh transistor is connected to a second initial signal line; the seventh gate electrode is arranged in the first gate metal layer, the first scan signal line is arranged in the first source drain metal layer, and the first scan signal line is connected to the seventh gate electrode through a seventh gate via.

9. The display substrate of claim 8, wherein in a unit row direction, seventh gate electrodes in at least one adjacent two circuit units are of an interconnected integral structure.

10. The display substrate of claim 8, wherein the second initial signal line is in a straight line shape or a bend line shape extending along the unit row direction, the at least one circuit unit further comprises a second initial connection line, the second initial connection line is in a straight line shape or a bend line shape extending along a unit column direction, and the second initial connection line is connected to the second initial signal line to form a network communication structure for transmitting a second initial signal.

11. The display substrate of claim 10, wherein the second initial connection line is arranged in the first gate metal layer, and the second initial signal line is arranged in the first source drain metal layer.

12. The display substrate of claim 1, wherein the plurality of transistors at least comprise a third transistor as a drive transistor, a fifth transistor as a first light emitting control transistor, and a sixth transistor as a second light emitting control transistor; the fifth transistor at least comprises a fifth gate electrode, the sixth transistor at least comprises a sixth gate electrode, the fifth gate electrode is connected to a first light emitting signal line, a first electrode of the fifth transistor is connected to a first power supply line, a second electrode of the fifth transistor is connected to a first electrode of the third transistor, the sixth gate electrode is connected to a second light emitting signal line, and a first electrode of the sixth transistor is connected to a second electrode of the third transistor; the fifth gate electrode and the sixth gate electrode are arranged in the first gate metal layer, the first light emitting signal line and the second light emitting signal line are arranged in the first source drain metal layer, the first light emitting signal line is connected to the fifth gate electrode through a via, and the second light emitting signal line is connected to the sixth gate electrode through a via.

13. The display substrate of claim 1, wherein the plurality of transistors at least comprise a third transistor as a drive transistor, a fifth transistor as a first light emitting control transistor, and a sixth transistor as a second light emitting control transistor; the fifth transistor at least comprises a fifth gate electrode, the sixth transistor at least comprises a sixth gate electrode, the fifth gate electrode is connected to a light emitting signal line, a first electrode of the fifth transistor is connected to a first power supply line, a second electrode of the fifth transistor is connected to a first electrode of the third transistor, the sixth gate electrode is connected to the light emitting signal line, and a first electrode of the sixth transistor is connected to a second electrode of the third transistor; the fifth gate electrode and the sixth gate electrode are arranged in the first gate metal layer, the light emitting signal line is arranged in the first source drain metal layer, and the light emitting signal line is connected to the fifth gate electrode and the sixth gate electrode through a same via.

14. The display substrate of claim 13, wherein in the at least one circuit unit, the fifth gate electrode and the sixth gate electrode are of an interconnected integral structure.

15. The display substrate of claim 13, wherein in a unit row direction, the sixth gate electrodes in at least one adjacent two circuit units are of an interconnected integral structure.

16. The display substrate of claim 1, wherein the pixel drive circuit further comprises a first capacitor and a second capacitor, the first capacitor comprises at least a first electrode plate and a third electrode plate, an orthographic projection of the first electrode plate on the substrate is at least partially overlapped with an orthographic projection of the third electrode plate on the substrate, the second capacitor at least comprises a second electrode plate and a fourth electrode plate, and an orthographic projection of the second electrode plate on the substrate is at least partially overlapped with an orthographic projection of the fourth electrode plate on the substrate.

17. The display substrate according to claim 1, wherein the pixel drive circuit further comprises a storage capacitor, the storage capacitor at least comprises a fifth electrode plate and a sixth electrode plate, and an orthographic projection of the fifth electrode plate on the substrate is at least partially overlapped with an orthographic projection of the sixth electrode plate on the substrate; the fifth electrode plate is arranged in the first gate metal layer, and the sixth electrode plate is arranged in the first source drain metal layer.

18. A display apparatus, comprising a display substrate according to claim 1.

19. A preparation method for a display substrate, wherein the display substrate comprises a plurality of circuit units forming a plurality of unit rows and a plurality of unit columns, at least one circuit unit comprises a pixel drive circuit and a plurality of scan signal lines connected to the pixel drive circuit, and the pixel drive circuit at least comprises a plurality of transistors; the preparation method comprising:
forming a first gate metal layer on a substrate, wherein a gate electrode of at least one transistor is arranged in the first gate metal layer; and
forming a first source drain metal layer on the first gate metal layer, wherein at least one scan signal line is arranged on the first source drain metal layer, and the scan signal line is connected to the gate electrode through a via.

20. The display substrate of claim 16, wherein the first electrode plate and the second electrode plate are arranged in the first gate metal layer, and the third electrode plate and the fourth electrode plate are arranged in the first source drain metal layer, and are of an interconnected integral structure.
